(19) United States
(12) Patent Application Publication
(10) Pub. No.: US 2025/0351338 A1
(43) Pub. Date: Nov. 13, 2025

(54) SEMICONDUCTOR DEVICES

(71) Applicant: Samsung Electronics Co., Ltd., Suwon-si (KR)

(72) Inventors: Juho Lee, Suwon-si (KR); Kyongjun Yoo, Suwon-si (KR); Seungmin Lee, Suwon-si (KR); Wonsok Lee, Suwon-si (KR); Sungduk Hong, Suwon-si (KR)

(21) Appl. No.: 19/018,233

(22) Filed: Jan. 13, 2025

(30) Foreign Application Priority Data
May 8, 2024 (KR) 10-2024-0060759

(51) Int. Cl. H10B 12/00

(52) U.S. Cl. CPC H10B 12/50; H10B 12/315; H10B 12/482; H10B 12/488

(57) ABSTRACT

A semiconductor device includes a substrate and a peripheral circuit area, and a cell array area at a distance from the substrate different from a distance of the peripheral circuit area from the substrate, and electrically connected to the peripheral circuit area by a bonding pad, wherein the cell array area includes a mold structure extending in a first horizontal direction, an active semiconductor layer on a sidewall of the mold structure and including a first oxide semiconductor, a word line on a sidewall of the active semiconductor layer, a cell capacitor on an upper surface of the active semiconductor layer, a bit line on a bottom surface of the active semiconductor layer and extending in a second horizontal direction, and an intermediate line between the bottom surface of the active semiconductor layer and the bit line, extending in the second horizontal direction, and including a second oxide semiconductor.

### CROSS-REFERENCE TO RELATED APPLICATION

This application is based on and claims priority under 35 U.S.C. § 119 to Korean Patent Application No. 10-2024-0060759, filed on May 8, 2024, in the Korean Intellectual Property Office, the disclosure of which is incorporated by reference herein in its entirety.

### BACKGROUND

The inventive concept relates to a semiconductor device, and more particularly, to a semiconductor device including a vertical channel transistor.

With the downscaling of semiconductor devices, sizes of dynamic random-access memory (DRAM) devices are also shrinking. In DRAM devices having a 1T-1C structure where one capacitor is connected to one capacitor, leakage current through a channel area becomes increasingly larger as devices becomes smaller. In order to reduce leakage current, a vertical channel transistor using an oxide semiconductor material as a channel layer has been proposed.

### SUMMARY

The inventive concept provides a semiconductor device with excellent electrical performance.

According to some embodiments of the inventive concept, there is provided a semiconductor device including a substrate, a peripheral circuit area on the substrate, and a cell array area at a distance from the substrate that is different from a distance of the peripheral circuit area from the substrate, the cell array area is electrically connected to the peripheral circuit area by a bonding pad. The cell array area includes a mold structure extending in a first horizontal direction, an active semiconductor layer on a sidewall of the mold structure and including a first oxide semiconductor, a word line on a sidewall of the active semiconductor layer, a cell capacitor on an upper surface of the active semiconductor layer, a bit line on a bottom surface of the active semiconductor layer and extending in a second horizontal direction that intersects the first horizontal direction, and an intermediate line between the bottom surface of the active semiconductor layer and the bit line, the intermediate line extending in the second horizontal direction, and including a second oxide semiconductor.

According to some embodiments of the inventive concept, there is provided a semiconductor device including a substrate, a peripheral circuit area on the substrate, and a cell array area on the peripheral circuit area, wherein the cell array area includes a plurality of mold structures extending in a first horizontal direction, a plurality of active semiconductor layers spaced apart from each other in the first horizontal direction, ones of the plurality of active semiconductor layers are between adjacent mold structures from among the plurality of mold structures, and extend in a vertical direction that intersects the first horizontal direction, a first word line and a second word line spaced apart from each other between adjacent mold structures from among the plurality of mold structures and extend in the first horizontal direction, a plurality of bit lines that are a first distance from the substrate that is less than a second distance of the plurality of active semiconductor layers from the substrate and less than a third distance of the plurality of mold structures from the substrate, the plurality of bit lines extend in a second horizontal direction that intersects the first horizontal direction and the vertical direction, and a plurality of intermediate lines between respective ones of the plurality of active semiconductor layers and respective ones of the plurality of bit lines and between the plurality of mold structures and the plurality of bit lines, and extending in the second horizontal direction.

According to some embodiments of the inventive concept, there is provided a semiconductor device including a peripheral circuit area including a substrate and a peripheral circuit transistor, and a cell array area on the peripheral circuit area, wherein the cell array area includes a mold structure extending in a first horizontal direction, an active semiconductor layer on a sidewall of the mold structure and including a first oxide semiconductor, a word line on a sidewall of the active semiconductor layer, a gate insulating layer between the sidewall of the active semiconductor layer and the word line, a landing pad on an upper surface of the active semiconductor layer, a cell capacitor on the landing pad, an intermediate line on a bottom surface of the active semiconductor layer and a bottom surface of the mold structure, the intermediate line extending in a second horizontal direction and including a second oxide semiconductor, a bit line on a bottom surface of the intermediate line and extending in the second horizontal direction, a bit line insulating layer on the bit line and on a sidewall of the intermediate line, and a shield metal layer at a side of the bit line with the bit line insulating layer therebetween.

### BRIEF DESCRIPTION OF THE DRAWINGS

Embodiments of the inventive concept will be more clearly understood from the following detailed description taken in conjunction with the accompanying drawings in which:

FIG. 1 is a schematic diagram illustrating a semiconductor device according to embodiments;

FIG. 2 is an enlarged layout diagram of a cell array area portion of FIG. 1;

FIG. 3 is a cross-sectional view of a layout of FIG. 2, taken along line A1-A1′;

FIG. 4 is a cross-sectional view taken along line A2-A2′ of FIG. 2;

FIG. 5 is an enlarged diagram of region CX1 of FIG. 3;

FIG. 6 is an enlarged diagram of region CX2 of FIG. 3;

FIGS. 7 and 8 are cross-sectional views illustrating a semiconductor device according to embodiments;

FIG. 9 is an enlarged diagram of region CX2 of FIG. 8;

FIGS. 10A, 10B, 11A, 11B, 12A, 12B, 13A, 13B, 13C, 14A, 14B, 14C, 15A, 15B, 15C, 16A, 16B, 16C, 17A, 17B, 18A, 18B, 19A, 19B, 20A, 20B, 20C, 21A, 21B, 21C, and 22 to 24 are schematic diagrams illustrating a method of manufacturing a semiconductor device, according to embodiments;

### DETAILED DESCRIPTION OF THE EMBODIMENTS

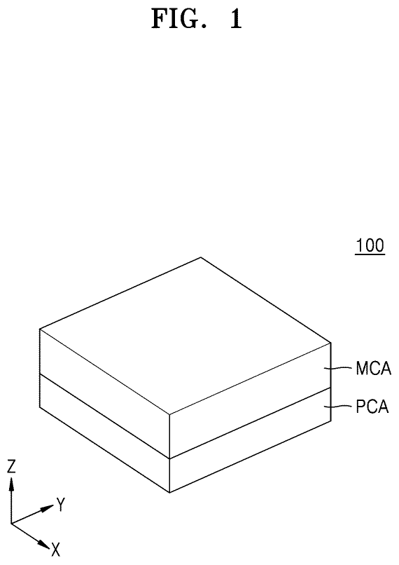

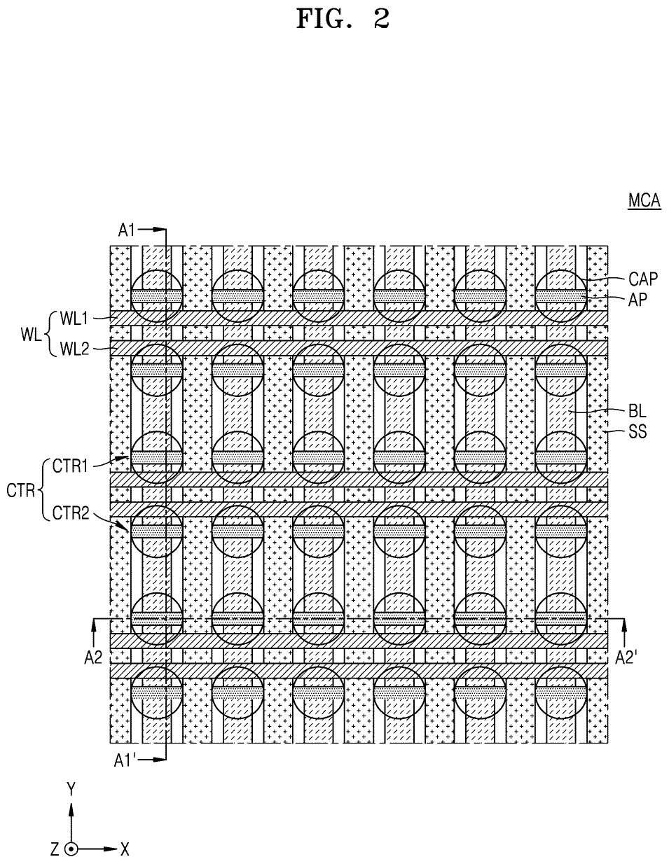

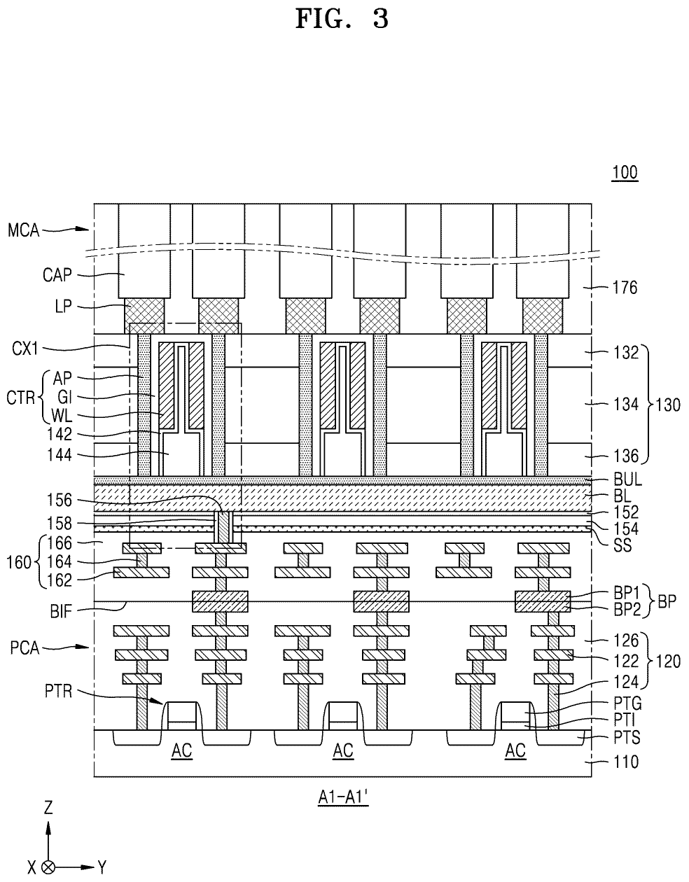

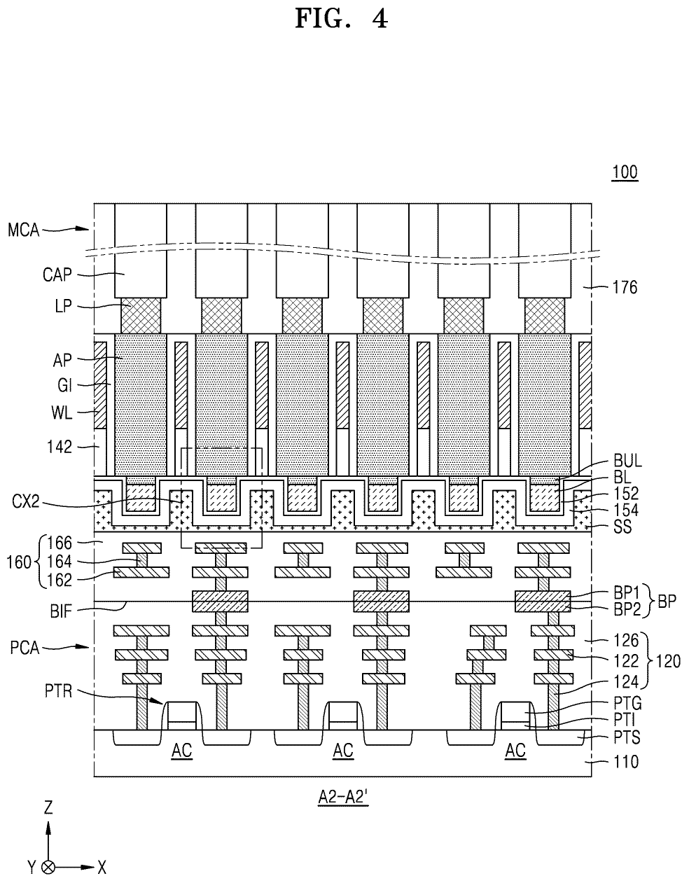

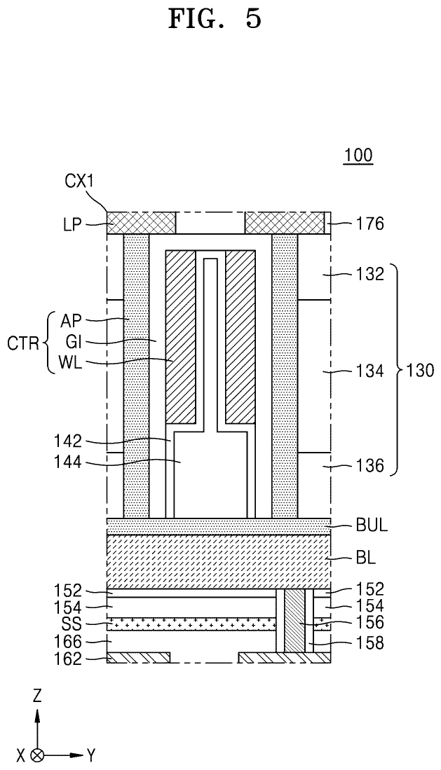

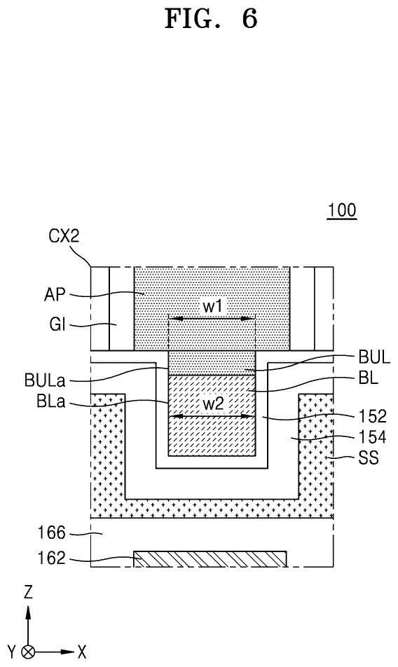

FIG. 1 is a schematic diagram illustrating a semiconductor device 100 according to embodiments. FIG. 2 is an enlarged layout diagram of a cell array area MCA portion of FIG. 1. FIG. 3 is a cross-sectional view of a layout of FIG. 2, taken along line A1-A1′. FIG. 4 is a cross-sectional view taken along line A2-A2′ of FIG. 2. FIG. 5 is an enlarged diagram of region CX1 of FIG. 3. FIG. 6 is an enlarged diagram of region CX2 of FIG. 3.

Referring to FIGS. 1 to 6, the semiconductor device 100 may include a peripheral circuit area PCA and the cell array area MCA that is at a higher vertical level than the peripheral circuit area PCA.

In some embodiments, the cell array area MCA may be a memory cell area of a dynamic random-access memory (DRAM) device, and the peripheral circuit area PCA may be a core area or peripheral circuit area of the DRAM device. For example, the peripheral circuit area PCA may include a peripheral circuit transistor PTR for transferring signals and/or power to a memory cell array included in the cell array area MCA. In embodiments, the peripheral circuit transistor PTR may configure various circuits such as a command decoder, a control logic, an address buffer, a row decoder, a column decoder, a sense amplifier, or a data input/output circuit.

As shown in FIG. 2, a plurality of word lines WL extending in a first horizontal direction X and a plurality of bit lines BL extending in a second horizontal direction Y may be arranged in the cell array area MCA. A plurality of cell transistors CTR may be at an intersection of the plurality of word lines WL and the plurality of bit lines BL. A plurality of cell capacitors CAP may be disposed on the plurality of cell transistors CTR, respectively.

The plurality of word lines WL may include a first word line WL1 and a second word line WL2 that are alternately arranged in the second horizontal direction Y, and the plurality of cell transistors CTR may include a first cell transistor CTR1 and a second cell transistor CTR2 that are alternately arranged in the second horizontal direction Y. The first cell transistor CTR1 may be arranged adjacent to the first word line WL1 , and the second cell transistor CTR2 may be arranged adjacent to the second word line WL2. The first cell transistor CTR1 and the second cell transistor CTR2 may have a mirror symmetrical structure with respect to each other. For example, the first cell transistor CTR1 and the second cell transistor CTR2 may have a mirror symmetrical structure with respect to a center line between the first cell transistor CTR1 and the second cell transistor CTR2, which extend in the first horizontal direction X.

In embodiments, a pitch of the plurality of bit lines BL (e.g., the sum of a width of one bit line BL and an interval between two adjacent bit lines BL) may be 2F, a pitch of the first word line WL1 may be 2F (or a pitch of the second word line WL2 may be 2F), and a unit area for forming one cell transistor CTR may be 4F2. Accordingly, because the cell transistor CTR may have a cross-point type that requires a relatively small unit area, it may be advantageous for improving integration of the semiconductor device 100.

Although not shown, an edge area may be arranged around the cell array area MCA. The edge area may be an area in which an electrical connection member for a word line WL and/or an electrical connection member for a bit line BL may be arranged, and may be an area in which an electrical connection member enabling electrical connection between the cell array area MCA and the peripheral circuit area PCA may be arranged.

Below, as shown in FIGS. 3 and 4, it is described that the cell array area MCA is at a higher vertical level (e.g., when the cell array area MCA is disposed on the peripheral circuit area PCA). In this case, the cell array area MCA is at a first distance from the substrate and the peripheral circuit area PCA is at a second distance that is less than the first distance from the substrate. However, the semiconductor device 100 may be arranged upside down so that the cell array area MCA is at a lower vertical level than the peripheral circuit area PCA, and in this case, it should be understood that, in the description below, “upper surfaces” or “bottom surfaces” of elements may also indicate “bottom surfaces” or “upper surfaces” of the elements, respectively, that elements described as being “over” or “under” an element may also indicate “under” or “over” the element, respectively, and that an element described as being “at a higher vertical level” may also indicate “at a lower vertical level”.

A substrate 110 may include, for example, single crystalline silicon, polycrystalline silicon, or amorphous silicon. In some other embodiments, the substrate 110 may include at least one selected from among germanium (Ge), silicon-germanium (SiGe), silicon carbide (SIC), gallium arsenide (GaAs), indium arsenide (InAs), and indium phosphide (InP). In some embodiments, the substrate 110 may include a conductive area, e.g., a well doped with impurities, or a structure doped with impurities.

In the peripheral circuit area PCA, an active area AC may be defined in the substrate 110, and the peripheral circuit transistor PTR may be disposed on the active area AC. The peripheral circuit transistor PTR may include a gate electrode PTG, a gate insulating layer PTI, and a source/drain area PTS.

The peripheral circuit transistor PTR and a peripheral circuit line structure 120 may be disposed on the substrate 110. The peripheral circuit line structure 120 may include a peripheral circuit line 122, a peripheral circuit contact 124, and a peripheral circuit insulating layer 126. The peripheral circuit line 122 and the peripheral circuit contact 124 may be electrically connected to the peripheral circuit transistor PTR and/or the substrate 110, and on the substrate 110, the peripheral circuit insulating layer 126 may cover or overlap the peripheral circuit transistor PTR, the peripheral circuit line 122, and the peripheral circuit contact 124. The peripheral circuit insulating layer 126 may include an oxide film, a nitride film, a low-k dielectric film, or a combination thereof, and may be formed of a stacked structure of a plurality of insulating layers.

The peripheral circuit area PCA may be attached to the cell array area MCA by a bonding method. In embodiments, a boundary between the peripheral circuit area PCA and the cell array area MCA may be referred to as a bonding interface BIF. For example, a portion of the semiconductor device 100 at a lower vertical level with respect to substrate 110 than the bonding interface BIF shown in FIG. 3 may be referred to as the peripheral circuit area PCA, and a portion at a higher vertical level with respect to substrate 110 than the bonding interface BIF may be referred to as the cell array area MCA.

In embodiments, the peripheral circuit line structure 120 and a cell wiring structure 160 may be in contact with each other with the bonding interface BIF therebetween. The cell wiring structure 160 may include a cell wiring layer 162, a cell contact 164, and a cell insulating layer 166.

A bonding pad BP may be at an interface between the cell wiring structure 160 and the peripheral circuit line structure 120 (e.g., at the bonding interface BIF). The bonding pad BP may include a first bonding pad BP1 and a second bonding pad BP2. An upper surface of the first bonding pad BP1 may be at the same level as an upper surface of the peripheral circuit insulating layer 126, a bottom surface of the second bonding pad BP2 may be at the same level as a bottom surface of the cell insulating layer 166, and the upper surface of the first bonding pad BP1 may be in contact with the bottom surface of the second bonding pad BP2.

In embodiments, the cell wiring structure 160 and the peripheral circuit line structure 120 may attached to each other by a metal-oxide hybrid bonding method, and in this case, an interface between the peripheral circuit insulating layer 126 and the cell insulating layer 166 may be coplanar with the interface between the first bonding pad BP1 and the second bonding pad BP2 (e.g., the interface between the peripheral circuit insulating layer 126 and the cell insulating layer 166 and the interface between the first bonding pad BP1 and the second bonding pad BP2 may be arranged along the bonding interface BIF).

In other embodiments, the cell wiring structure 160 and the peripheral circuit line structure 120 may be attached to each other by an oxide bonding method, in which case the bonding pad BP may be omitted.

The plurality of bit lines BL may be disposed on the cell wiring structure 160, the cell transistor CTR may be disposed on the plurality of bit lines BL, and the cell transistor CAP may be disposed on the cell transistor CTR. In embodiments, the bit line BL may be arranged closer to the bonding interface BIF than the cell transistor CTR or the cell transistor CAP. Accordingly, a vertical distance between the bit line BL and the peripheral circuit transistor PTR may be less than a vertical distance between the cell transistor CAP and the peripheral circuit transistor PTR.

In embodiments, the plurality of bit lines BL may extend in the second horizontal direction Y and a shield metal layer SS may be arranged in a space between the plurality of bit lines BL. For example, the plurality of bit lines BL may be arranged to extend in the second horizontal direction Y, a portion of the shield metal layer SS may be arranged to extend in the second horizontal direction Y and fill the space between the plurality of bit lines BL, and another portion of the shield metal layer SS may be disposed between the bottom surfaces of the plurality of bit lines BL and the upper surface of the cell wiring structure 160. A sidewall and bottom surface of the bit line BL may be covered by or overlapped by a first bit line insulating layer 152 and a second bit line insulating layer 154, and the first bit line insulating layer 152 and the second bit line insulating layer 154 may be interposed between the sidewall of the bit line BL and the shield metal layer SS and between the bottom surface of the bit line BL and the shield metal layer SS.

In embodiments, the bit line BL may include titanium (Ti), titanium nitride (TiN), tantalum (Ta), tantalum nitride (TaN), molybdenum (Mo), ruthenium (Ru), tungsten (W), tungsten nitride (WN), cobalt (Co), nickel (Ni), titanium silicide (TiSi), titanium silicon nitride (TiSiN), tungsten silicide (WSi), tungsten silicon nitride (WSiN), tantalum silicide (TaSi), tantalum silicon nitride (TaSiN), ruthenium titanium nitride (RuTiN), cobalt silicide (CoSi), nickel silicide (NiSi), polysilicon, or a combination thereof. In embodiments, the shield metal layer SS may include Ti, TiN, Ta, TaN, Mo, Ru, W, WN, Co, Ni, copper (Cu), aluminum (Al), TiSi, TiSiN, WSi, WSiN, TaSi, TaSiN, RuTiN, CoSi, NiSi, or a combination thereof.

A bit line contact 156 may be disposed between the bottom surface of the bit line BL and the cell wiring layer 162, and a sidewall of the bit line contact 156 may be surrounded by a bit line contact spacer 158. The bit line contact 156 may be electrically insulated from the shield metal layer SS by the bit line contact spacer 158.

A plurality of intermediate lines BUL may be respectively disposed on upper surfaces of the plurality of bit lines BL. The plurality of intermediate lines BUL may be arranged to extend in the second horizontal direction Y and cover or overlap the respective upper surfaces of the plurality of bit lines BL. Sidewalls BULa of the plurality of intermediate lines BUL may be covered by or overlapped by the first bit line insulating layer 152.

In embodiments, the plurality of intermediate lines BUL may include an oxide semiconductor, and for example, the oxide semiconductor may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), or zirconium zinc tin oxide (ZrₓZn_{y}Sn_{z}O). In embodiments, the plurality of intermediate lines BUL may include a semiconductor material such as silicon, germanium, or silicon-germanium. In embodiments, the plurality of intermediate lines BUL may further include n-type impurity ions. For example, the n-type impurity ions may be doped into the plurality of intermediate lines BUL through an ion implant process or the like.

In embodiments, the sidewall BULa of each of the plurality of intermediate lines BUL may be aligned with a sidewall BLa of each of the plurality of bit lines BL. In embodiments, each of the plurality of intermediate lines BUL may have a first width w1 in the first horizontal direction X, each of the plurality of bit lines BL may have a second width w2 in the first horizontal direction X, and the first width w1 may be equal or similar to the second width w2. Here, the first width w1 being equal or similar to the second width w2 may denote that the second width w2 has a value within a tolerance range from the first width w1 (e.g., the first width w1 has a value within a range considering tolerances or errors in a manufacturing process, such as a value within ±5% of the first width w1 or a value within ±10% of the first width).

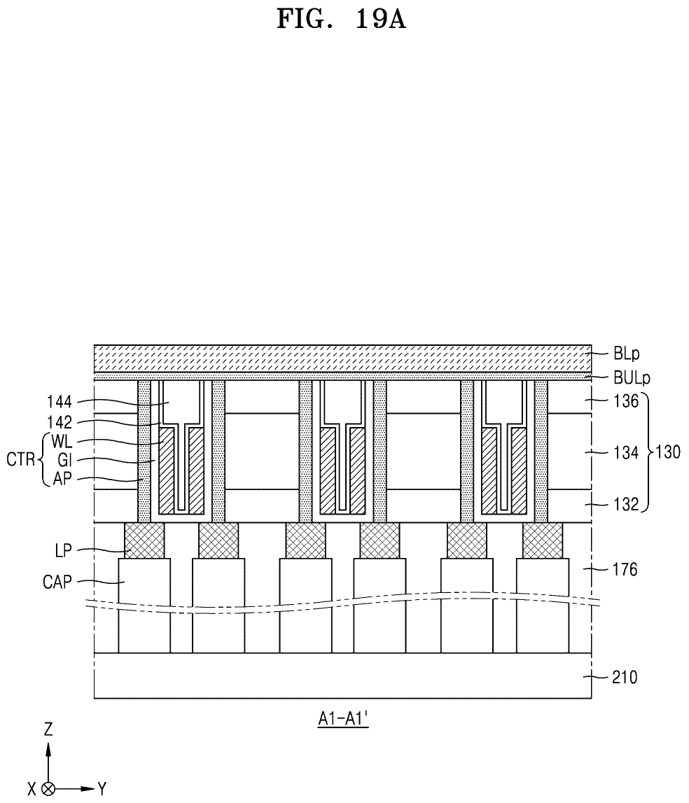

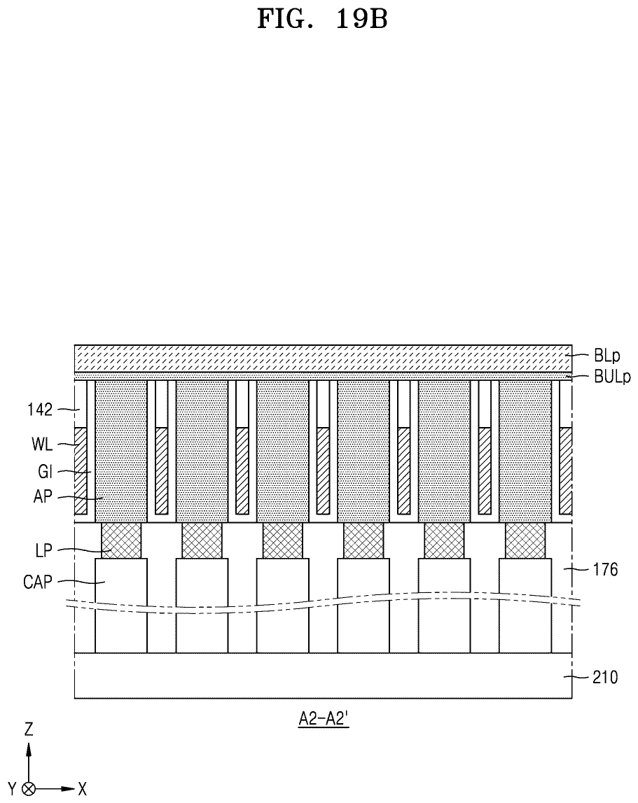

In embodiments, the plurality of intermediate lines BUL may be patterned together in a patterning process for the plurality of bit lines BL. For example, an intermediate line layer BULp (see FIGS. 19A and 19B) and a bit line BLp (see FIGS. 19A and 19B) may be sequentially formed on a mold structure 130 and the cell transistor CTR, and then the intermediate line layer BULp (see FIGS. 19A and 19B) and the bit line BLp (see FIGS. 19A and 19B) may be patterned into line types to form the plurality of intermediate lines BUL and the plurality of bit lines BL. In this case, the sidewall BULa of each of the plurality of intermediate lines BUL and the sidewall BLa of each of the plurality of bit lines BL may be aligned with each other.

In some embodiments, in the patterning process for forming the plurality of intermediate lines BUL and the plurality of bit lines BL, parts of the plurality of bit lines BL may be exposed to the etching atmosphere for a longer period of time, and in this case, the sidewall BLa of the plurality of bit lines BL may be inclined at a certain angle.

In embodiments, the bit line BL may have a flat top level and a flat bottom level. In embodiment, the bit line BL may have a planar top surface and a planar bottom surface. For example, the bit line BL may have a uniform thickness in a vertical direction Z across the entire length thereof along the second horizontal direction Y. In addition, the intermediate line BUL may have a flat top level and a flat bottom level. In embodiment, the intermediate line BUL may have a planar top surface and a planar bottom surface. For example, the intermediate line BUL may have a uniform thickness in the vertical direction Z across the entire length thereof along the second horizontal direction Y.

The plurality of mold structures 130 and the plurality of cell transistors CTR may be disposed on the upper surfaces of the plurality of intermediate lines BUL. For example, each of the plurality of mold structures 130 may extend in the first horizontal direction X, and the plurality of cell transistors CTR may be disposed on opposite sidewalls of each of the mold structures 130.

Each of the plurality of mold structures 130 may include a first mold layer 132, a second mold layer 134, and a third mold layer 136, which are disposed in the vertical direction Z. For example, the third mold layer 136 may be disposed on the intermediate line BUL and the first bit line insulating layer 152, and for example, the third mold layer 136 may be arranged in contact with the intermediate line BUL and the first bit line insulating layer 152. The second mold layer 134 may be disposed on the third mold layer 136, and the first mold layer 132 may be disposed on the second mold layer 134.

In embodiments, each of the first, second, and third mold layers 132, 134, and 136 may include at least one of silicon oxide, silicon nitride, silicon oxynitride, and/or a low-k dielectric material. In some embodiments, the first mold layer 132 and the third mold layer 136 may include silicon nitride or silicon oxynitride, and the second mold layer 134 may include silicon oxide or a low-k dielectric material.

In embodiments, the cell transistor CTR may include an active semiconductor layer AP, a gate insulating layer GI, and a word line WL, which are sequentially disposed on a sidewall of the mold structure 130.

In embodiments, the active semiconductor layer AP may extend in the vertical direction Z, and may have an upper surface disposed coplanar with the upper surface of the mold structure 130, and a bottom surface disposed coplanar with the bottom surface of the mold structure 130. The bottom surface of the active semiconductor layer AP and the bottom surface of the mold structure 130 may be in contact with the upper surface of the intermediate line BUL.

In embodiments, the active semiconductor layer AP may include at least one of ZnₓSn_{y}O, InₓZn_{y}O, ZnOₓ, InₓGa_{y}Zn_{z}O, InₓGa_{y}Si_{z}O, InₓW_{y}O, InₓO, SnₓO, TiₓO, ZnₓON_{z}, MgₓZn_{y}O, ZrₓIn_{y}Zn_{z}O, HfₓIn_{y}Zn_{z}O, SnₓIn_{y}Zn_{z}O, AlₓSn_{y}In_{z}ZnₐO, SiₓIn_{y}Zn_{z}O, AlₓZn_{y}Sn_{z}O, GaₓZn_{y}Sn_{z}O, or ZrₓZn_{y}Sn_{z}O. In embodiments, the active semiconductor layer AP may further include n-type impurity ions. For example, the n-type impurity ions may be doped into the active semiconductor layer AP through an ion implant process or the like.

The gate insulating layer GI may be further disposed on a sidewall of the active semiconductor layer AP. In embodiments, the gate insulating layer GI may include at least one selected from among a high-k dielectric material having a higher dielectric constant than silicon oxide, and a ferroelectric material. In some embodiments, the gate insulating layer GI may include at least one material selected from among hafnium oxide (HfO), hafnium silicate (HfSiO), hafnium oxynitride (HfON), hafnium silicon oxide nitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconium titanium oxide (PbZrTiO), strontium bismuth tantalum oxide (StBiTaO), bismuth iron oxide (BiFcO), strontium titanium oxide (SrTiO), yttrium oxide (YO), aluminum oxide (AlO), or lead scandium tantalum oxide (PbScTaO).

The word line WL may be disposed on a sidewall of the gate insulating layer GI. In some embodiments, the word line WL may include Ti, TiN, Ta, TaN, Mo, Ru, W, WN, TiSiN, WSiN, polysilicon, or a combination thereof. For example, two word lines WL may be spaced apart from each other between two adjacent mold structures 130 and may extend in the first horizontal direction X. For example, the first word line WL1 and the second word line WL2 may be spaced apart from each other between two adjacent mold structures 130. The upper surface of the word line WL may be covered by or overlapped by the gate insulating layer GI, and the bottom surface of the word line WL may be at a higher vertical level than the bottom surface of the active semiconductor layer AP.

An insulating liner 142 and a buried insulating layer 144 may be disposed between the first word line WL1 and the second word line WL2. The insulating liner 142 may be conformally disposed on the sidewalls and bottom surfaces of the first word line WL1 and the second word line WL2, and may be interposed between the word line WL and the buried insulating layer 144.

A plurality of landing pads LP may be disposed on the plurality of cell transistors CTR, and the cell transistor CAP may be disposed on each of the landing pads LP. The plurality of landing pads LP may include Ti, TiN, Ta, TaN, W, WN, TiSiN, WSiN, polysilicon, or a combination thereof. The cell transistor CAP may have a metal-insulator-metal type capacitor structure. For example, the cell transistor CAP may include a first electrode, a second electrode, and a capacitor dielectric layer that is interposed between the first electrode and the second electrode. An insulating layer 176 may be disposed on a sidewall of the landing pad LP and at least a part of the cell transistor CAP.

In a semiconductor device including an oxide semiconductor channel, according to the comparative example, after an active semiconductor layer AP is formed on a sidewall of a mold structure, a recess is formed by removing a portion of the active semiconductor, and a bit line BL is formed by burying a portion of a bit line BL within the recess (i.e., at a position from which the portion of the active semiconductor layer AP is removed). In this case, the bit line BL may include a first portion arranged within the recess and a second portion connected to the first portion and extending in a line shape. In other words, a vertical distance between the first portion of the bit line BL and a shield metal layer SS may be relatively large.

In the semiconductor device according to the comparative example, because the second portion of the bit line is shielded by the shield metal layer SS, capacitance due to bit line coupling is not large, but because the first portion of the bit line BL is not shielded by the shield metal layer SS, capacitance due to bit line coupling may be relatively large. For example, in the semiconductor device according to the comparative example, the capacitance due to bit line coupling may correspond to 21% of the total capacitance.

On the other hand, according to embodiments, a process of forming a recess by removing a portion of the active semiconductor layer AP may not be performed, and the bit line BL may be arranged in a line shape and the intermediate line BUL may be disposed between the bit line BL and the active semiconductor layer AP. Accordingly, according to embodiments, the first portion of the bit line BL formed in the comparative example may be omitted and the bit line BL may include only the second portion. In addition, the vertical distance between the bit line BL and the shield metal layer SS may be relatively small. Because the entire area of the bit line BL may be shielded by the shield metal layer SS, in the semiconductor device according to embodiments, capacitance due to bit line coupling may correspond to 4.2% of the total capacitance. Accordingly, according to embodiments, significantly lower coupling capacitance may be obtained compared to the comparative example.

Moreover, when the intermediate line BUL is disposed between the bit line BL and the active semiconductor layer AP, it is confirmed that electrical resistance between the bit line BL and the active semiconductor layer AP may be significantly reduced, and an operating current is increased by approximately 10% compared to the comparative example. Therefore, the semiconductor device 100 may have excellent electrical performance.

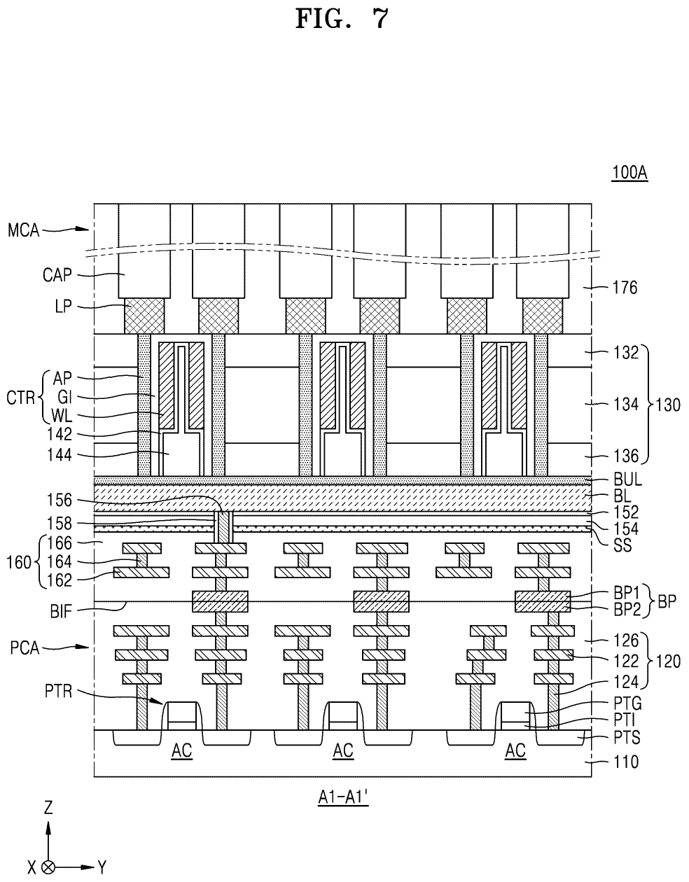

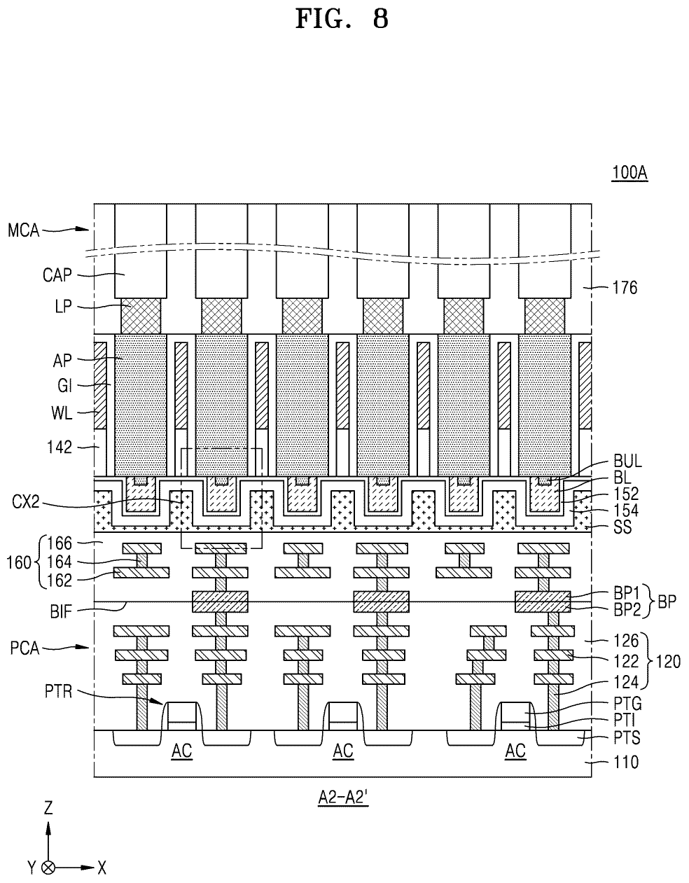

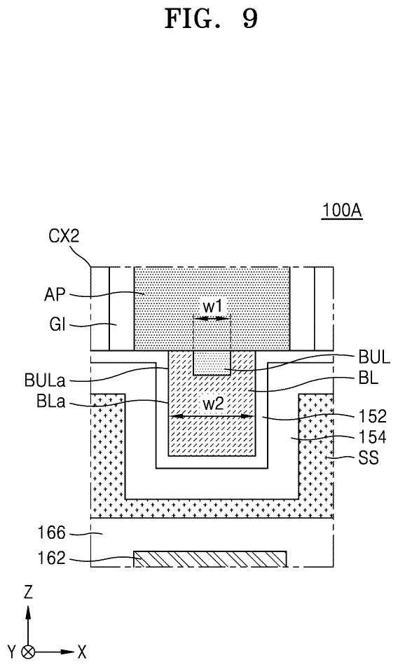

FIGS. 7 and 8 are cross-sectional views illustrating a semiconductor device 100A according to embodiments. FIG. 9 is an enlarged diagram of region CX2 of FIG. 8.

Referring to FIGS. 7 to 9, the plurality of intermediate lines BUL may have the first width w1 and the plurality of bit lines BL may have the second width w2, wherein the second width w2 may be greater than the first width w1. For example, the sidewalls BULa and bottom surfaces of the plurality of intermediate lines BUL may be covered by or overlapped by the bit line BL, and accordingly, a contact area between each of the plurality of intermediate lines BUL and a corresponding bit line BL may be increased. The sidewalls BULa of the plurality of intermediate lines BUL may be covered by or overlapped by the bit line BL, and may not be in direct contact with the first bit line insulating layer 152.

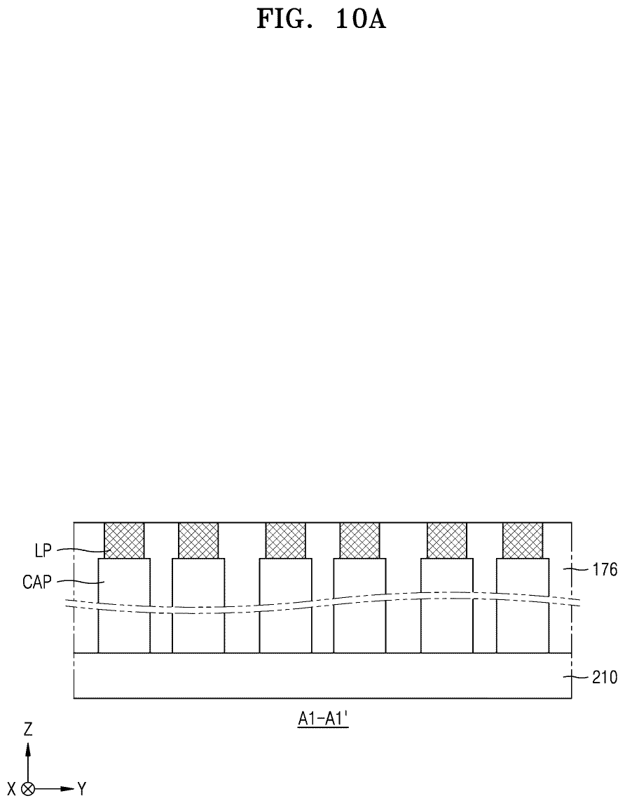

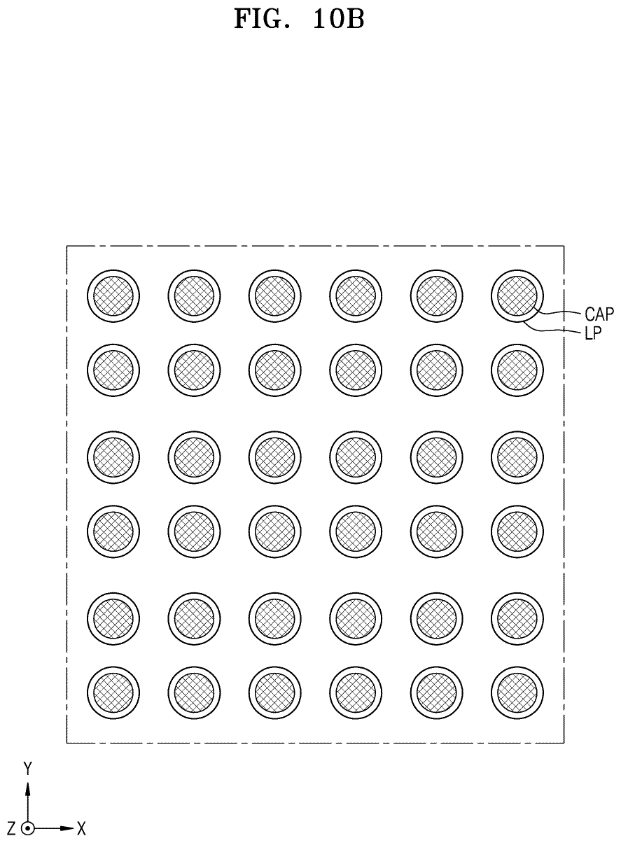

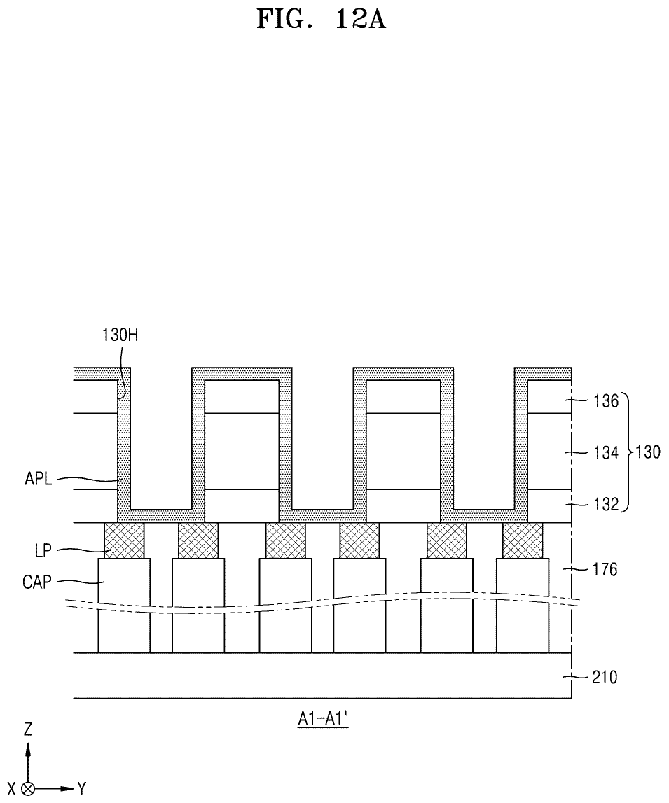

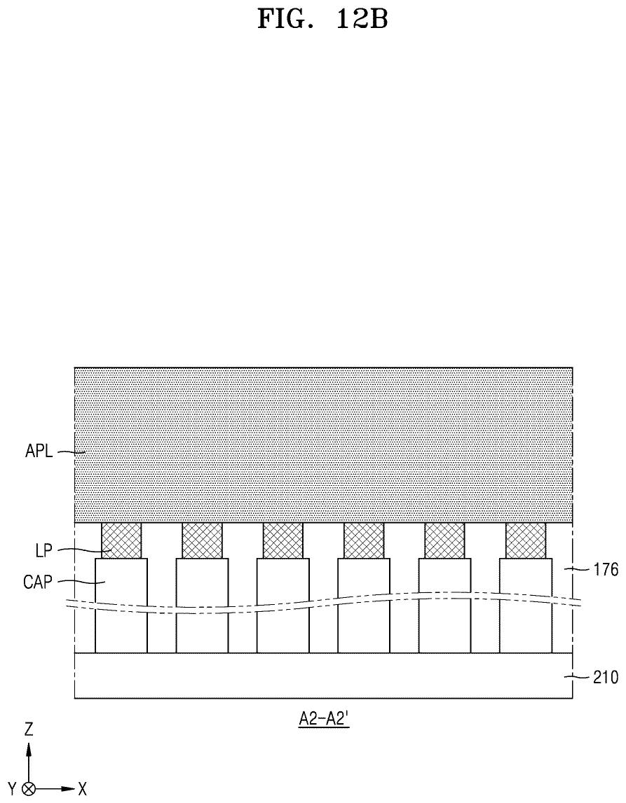

FIGS. 10A, 10B, 11A, 11B, 12A, 12B, 13A, 13B, 13C, 14A, 14B, 14C, 15A, 15B, 15C, 16A, 16B, 16C, 17A, 17B, 18A, 18B, 19A, 19B, 20A, 20B, 20C, 21A, 21B, 21C, and 22 to 24 are schematic diagrams illustrating a method of manufacturing the semiconductor device 100, according to embodiments. FIGS. 10A, 11A, 12A, 13A, 14A, 15A, 16A, 17A, 18A, 19A, 20A, 21A, and 22 to 24 are cross-sectional views taken along line A1-A1 of FIG. 2, FIGS. 12B, 13B, 14B, 15B, 16B, 17B, 18B, 19B, 20B, and 21B are cross-sectional views taken along line A2-A2 of FIG. 2, and FIGS. 10B, 11B, 13C, 14C, 15C, 16C, 20C, and 21C are plan views corresponding to the cross-sectional views of FIGS. 10A, 11A, 13A, 14A, 15A, 16A, 20A, and 21A, respectively.

Referring to FIGS. 10A and 10B, the cell transistor CAP may be formed on a carrier substrate 210, and the landing pad LP may be formed on the cell transistor CAP.

In embodiments, as shown in FIG. 10B, the cell transistor CAP and the landing pad LP may be arranged in a matrix shape. In other embodiments, the cell transistor CAP and the landing pad LP may be arranged in a hexagon.

In some embodiments, a capacitor mold insulating layer may be formed on the carrier substrate 210, and a capacitor opening extending in the vertical direction Z may be formed in the capacitor mold insulating layer, and the cell transistor CAP may be formed in the capacitor opening.

In some embodiments, an insulating layer 176 surrounding a sidewall of the landing pad LP in plan view may be formed. In some embodiments, the insulating layer 176 covering or overlapping the sidewall and upper surface of the cell transistor CAP may be first formed, then an opening may be formed in the insulating layer 176 to expose the upper surface of the cell transistor CAP, and the landing pad LP may be formed in the opening.

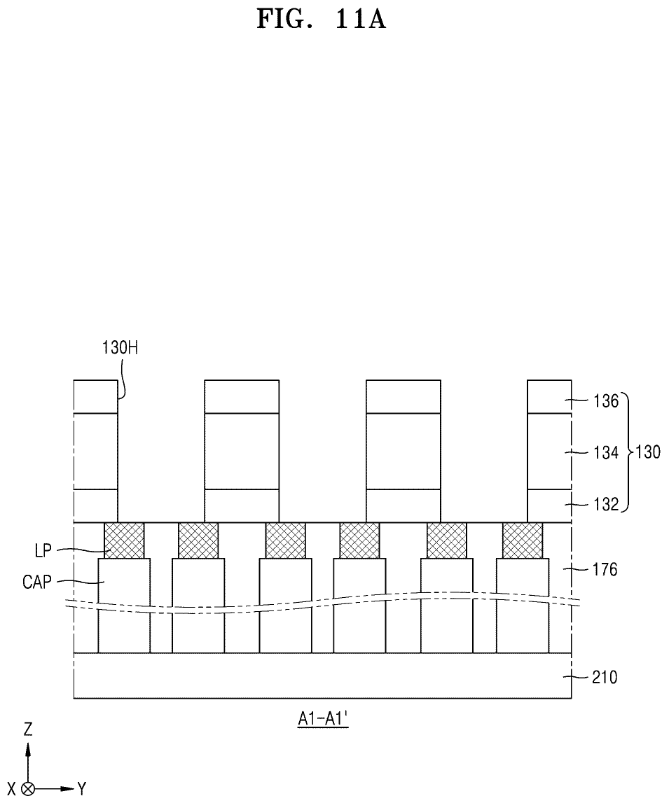

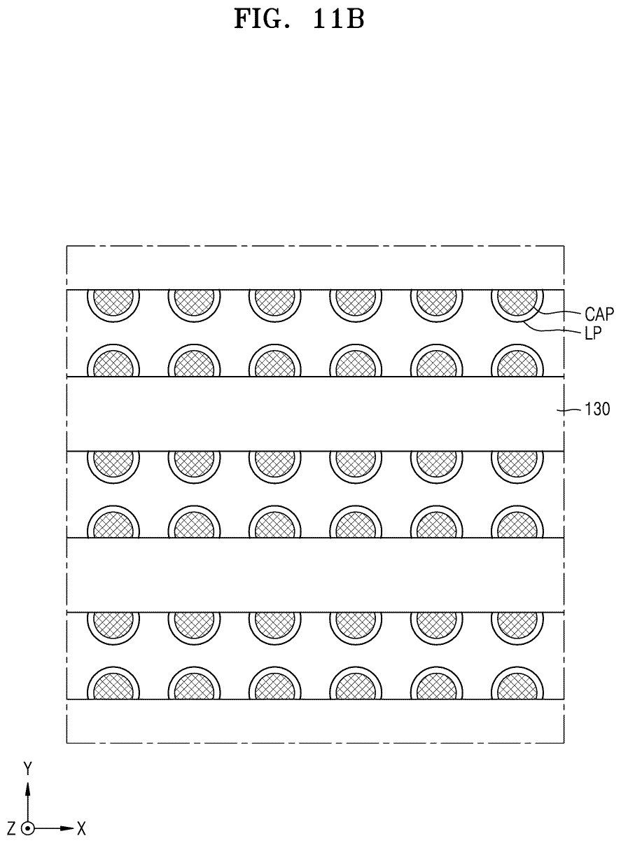

Referring to FIGS. 11A and 11B, the mold structure 130 extending in the first horizontal direction X may be formed on the landing pad LP and the insulating layer 176. The mold structure 130 may include the first mold layer 132, the second mold layer 134, and the third mold layer 136, which are sequentially disposed on the landing pad LP and the insulating layer 176. The mold structure 130 may have a sidewall 130H extending in the first horizontal direction X.

In embodiments, a width of the mold structure 130 in the second horizontal direction Y may be determined so that two landing pads LP are exposed in the second direction between two adjacent mold structures 130.

Referring to FIGS. 12A and 12B, a preliminary active semiconductor layer APL may be formed on the sidewall 130H of the mold structure 130. The preliminary active semiconductor layer APL may be conformally disposed on the sidewall 130H and upper surface of the mold structure 130, the upper surface of the landing pad LP, and the upper surface of the insulating layer 176. For example, a thickness of the preliminary active semiconductor layer APL disposed on the sidewall 130H of the mold structure 130 may be equal or similar to a thickness of the preliminary active semiconductor layer APL disposed on the upper surface of the mold structure 130, the upper surface of the landing pad LP, and the upper surface of the insulating layer 176.

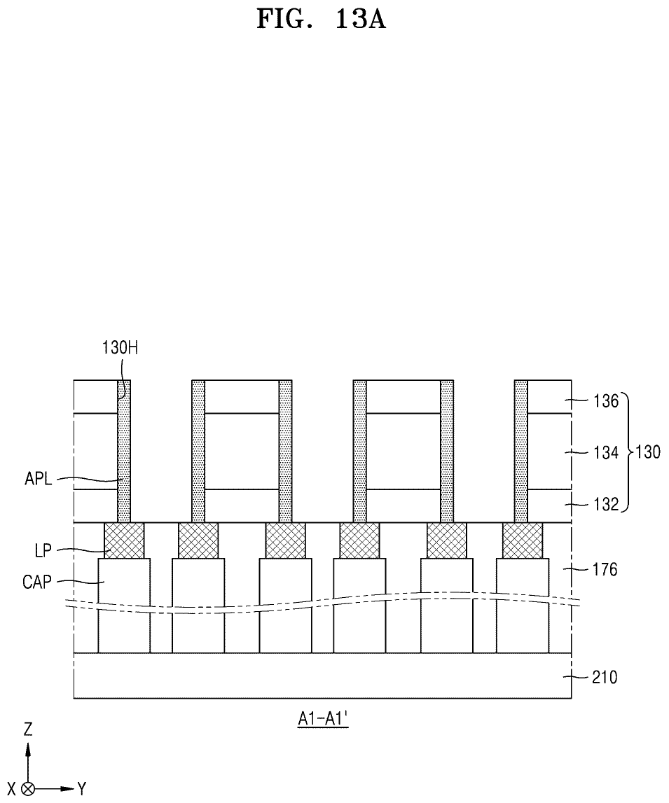

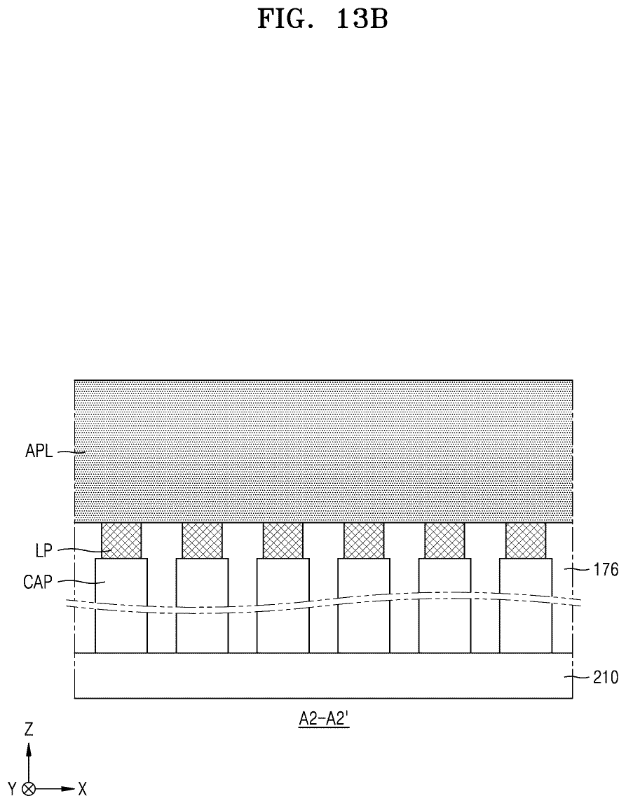

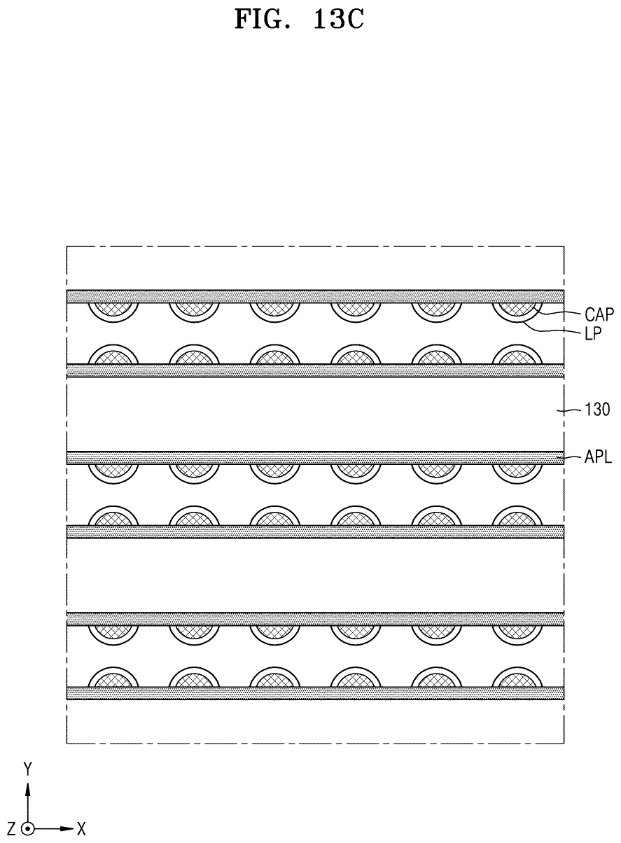

Referring to FIGS. 13A, 13B, and 13C, portions of the preliminary active semiconductor layer APL disposed on the upper surface of the mold structure 130 and the upper surface of the insulating layer 176 may be removed by performing an anisotropic etching process or an etch-back process, so that only a portion of the preliminary active semiconductor layer APL disposed on the sidewall 130H of the mold structure 130 may remain.

Due to the anisotropic etching process or the etch-back process, the upper surface of the mold structure 130 (e.g., an upper surface of the third mold layer 136) may be exposed again. The upper surface of the mold structure 130 (e.g., the upper surface of the third mold layer 136) may be at the same level as the upper surface of the preliminary active semiconductor layer APL. In addition, as shown in FIG. 13A, a bottom surface of the preliminary active semiconductor layer APL may be in contact with the upper surface of the landing pad LP. The preliminary active semiconductor layer APL may extend in the first horizontal direction X on a sidewall 130H of the mold structure 130.

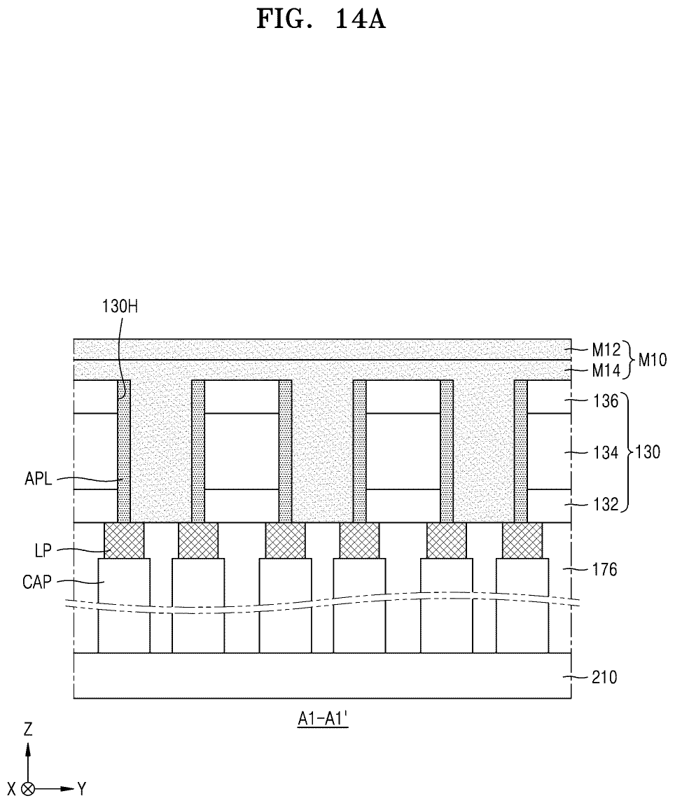

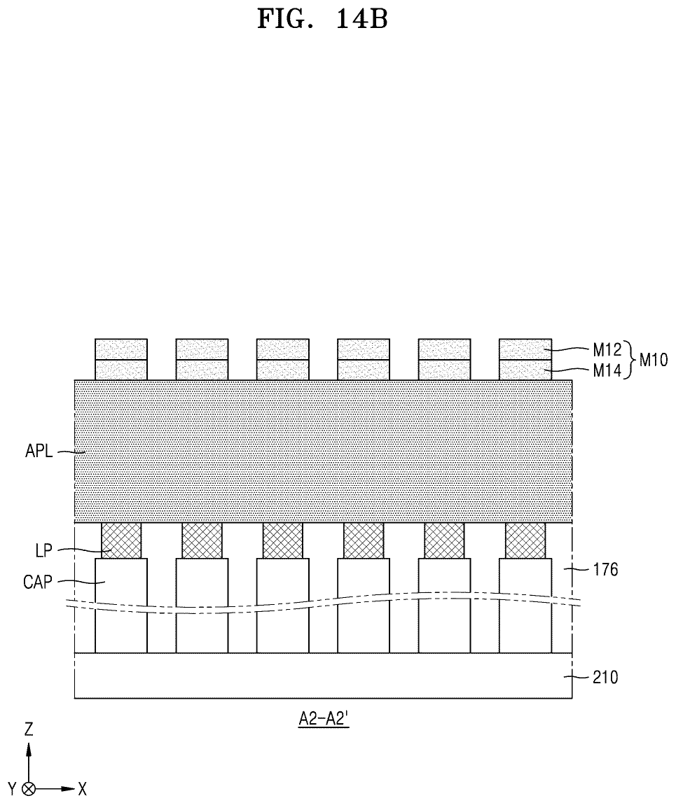

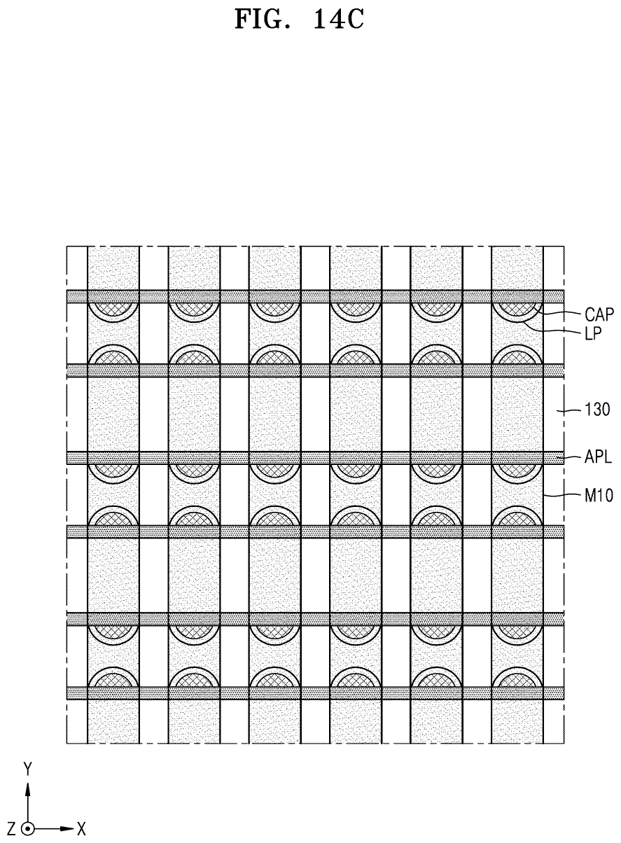

Referring to FIGS. 14A, 14B, and 14C, a mask pattern M10 extending in the second horizontal direction Y may be formed on the mold structure 130 and the preliminary active semiconductor layer APL.

In embodiments, the mask pattern M10 may include a lower mask layer M14 with which a space between two adjacent preliminary active semiconductor layer APL is partially or completely filled, and an upper mask layer M12 that is on the lower mask layer M14. For example, the lower mask layer M14 may include a silicon-on-hardmask, and the upper mask layer M12 may include silicon oxynitride.

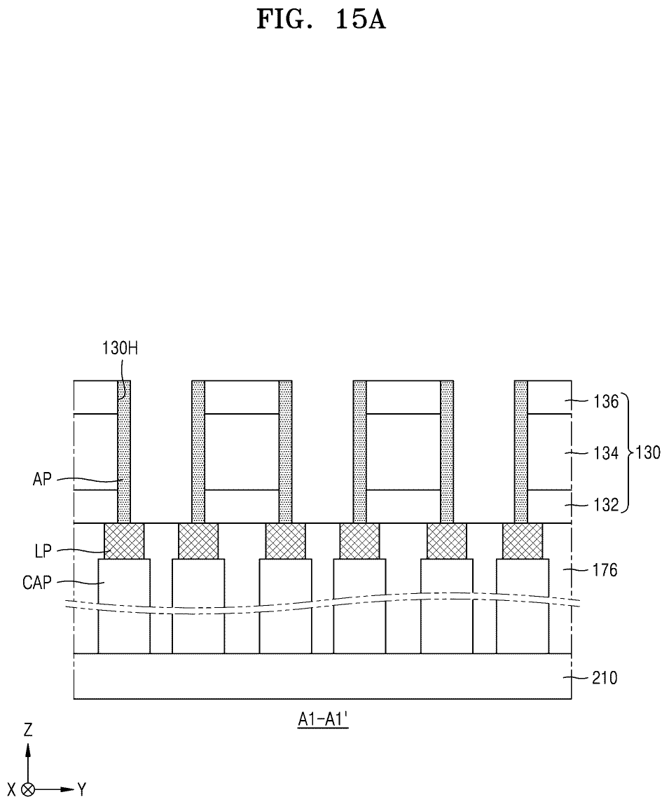

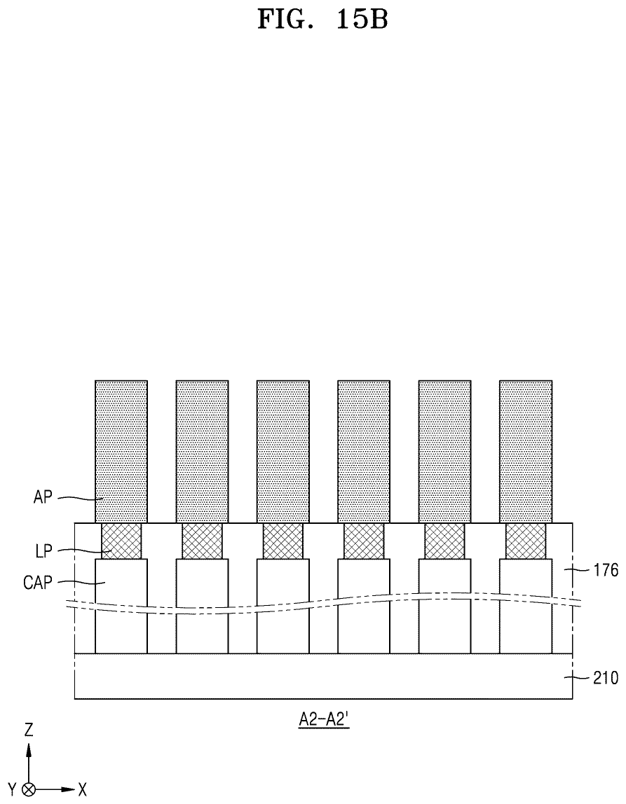

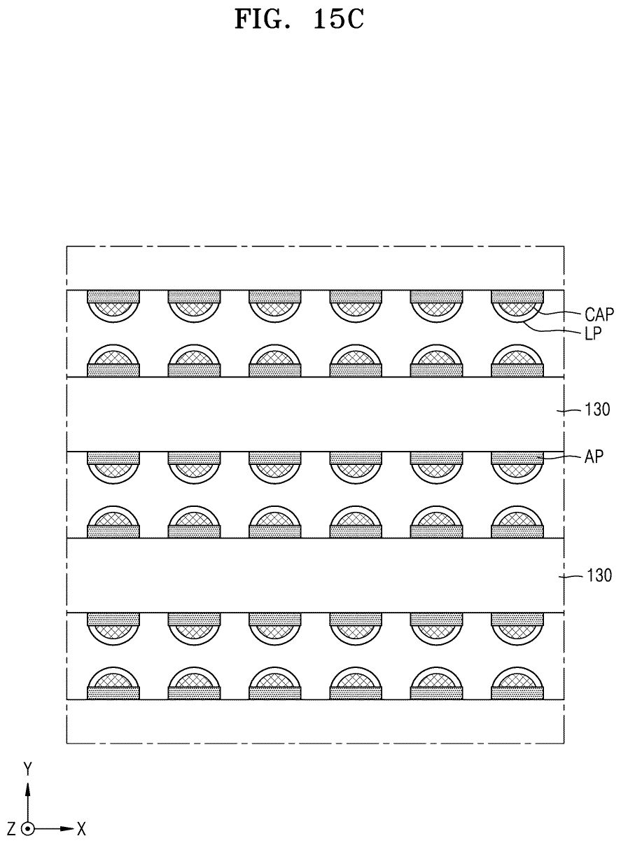

Referring to FIGS. 15A, 15B and 15C, a portion of the preliminary active semiconductor layer APL not covered by or not overlapped by the mask pattern M10 may be removed. Another portion of the preliminary active semiconductor layer APL covered by or overlapped by the mask pattern M10 may remain without being removed, and may be referred to as the active semiconductor layer AP. Two active semiconductor layers AP may be spaced apart from each other in the first horizontal direction X between two adjacent mold structures 130, and one active semiconductor layer AP may be disposed on one landing pad LP.

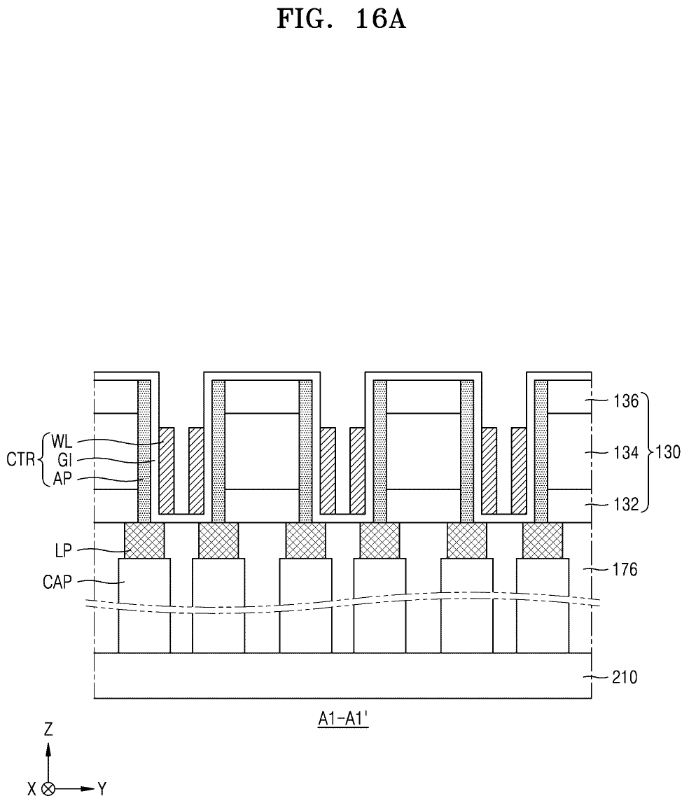

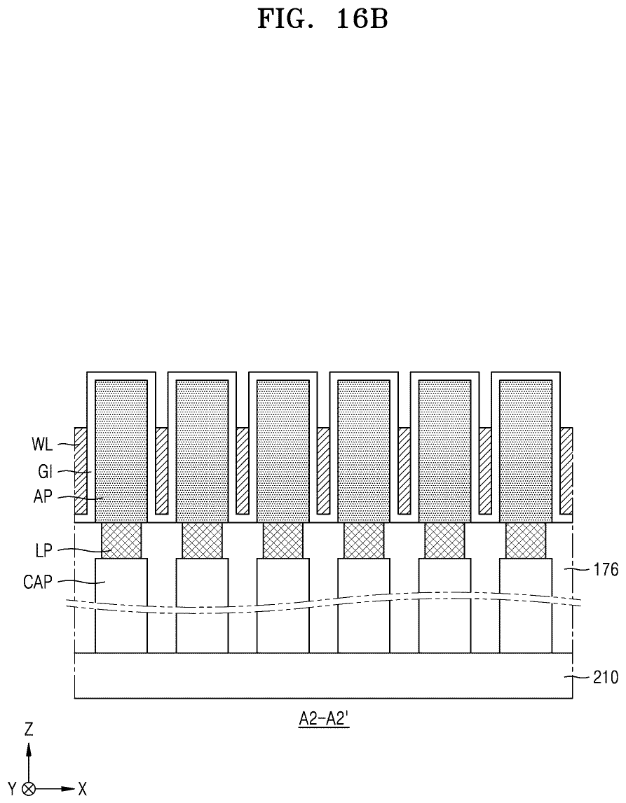

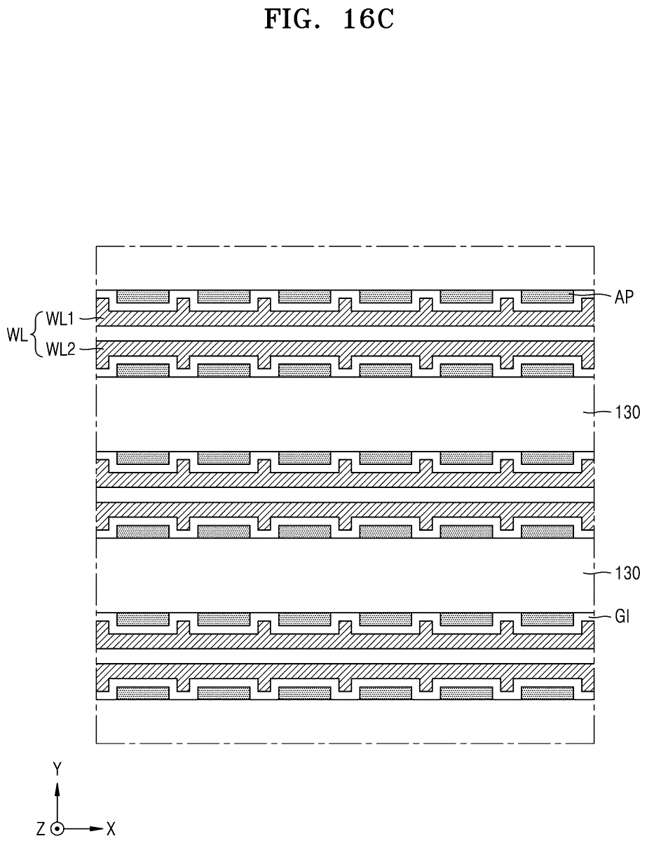

Referring to FIGS. 16A, 16B, and 16C, the gate insulating layer GI and the word line WL may be formed on a sidewall of the active semiconductor layer AP.

In embodiments, the gate insulating layer GI may be conformally formed on the upper surface of the mold structure 130, the sidewall of the active semiconductor layer AP, and the upper surface of the insulating layer 176.

Thereafter, the word line WL may be formed on the sidewall of the active semiconductor layer AP with the gate insulating layer GI therebetween. In an example process for forming the word line WL, the word line WL may be conformally formed on the upper surface and sidewall of the gate insulating layer GI, and then an anisotropic etching process or a recess process may be performed on the word line WL so that the word line WL may remain only between two mold structures 130 arranged adjacent to each other (e.g., only on the sidewall of the gate insulating layer GI).

As shown in FIG. 16C, between two mold structures 130 arranged adjacent to each other, the first word line WL1 may be disposed on the sidewall of the left mold structure 130 and the second word line WL2 may be disposed on the sidewall of the right mold structure 130.

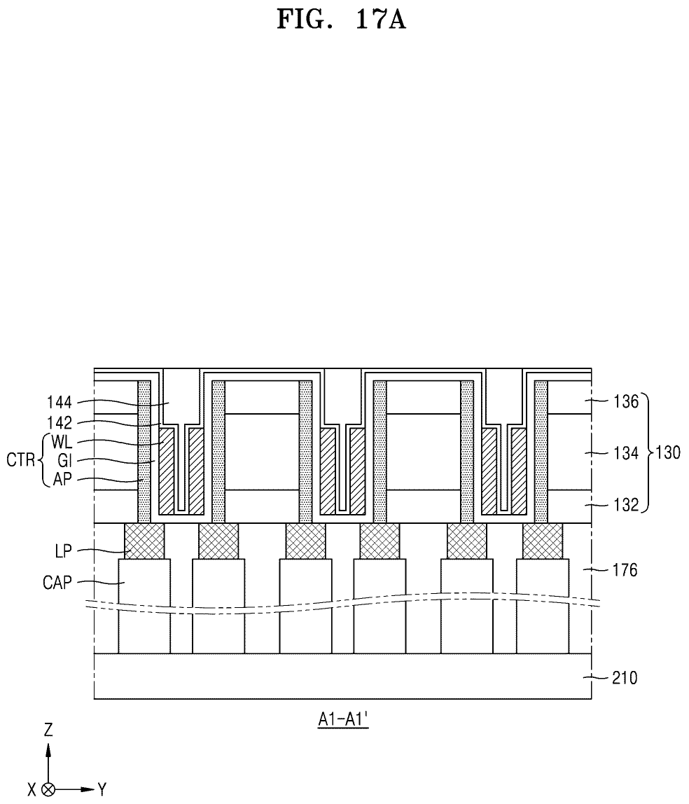

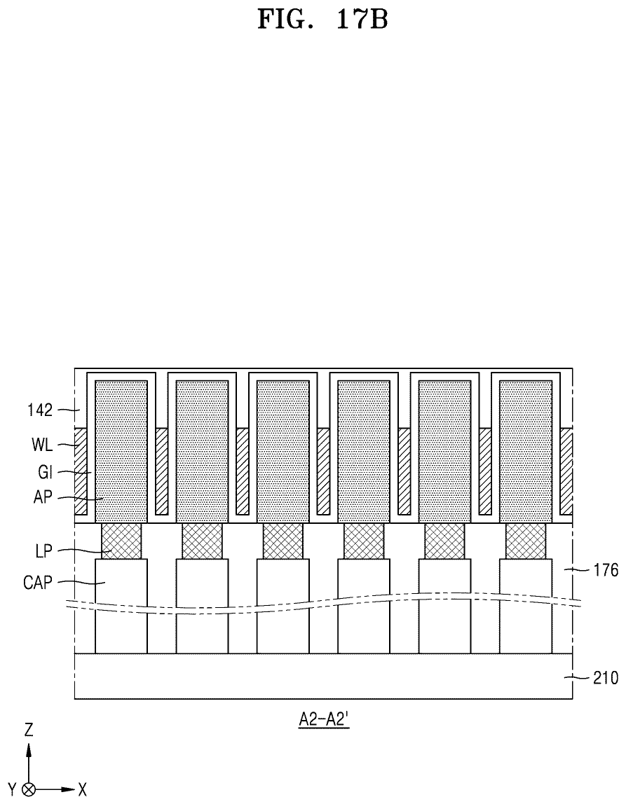

Referring to FIGS. 17A and 17B, the insulating liner 142 and the buried insulating layer 144 may be sequentially formed on the word line WL.

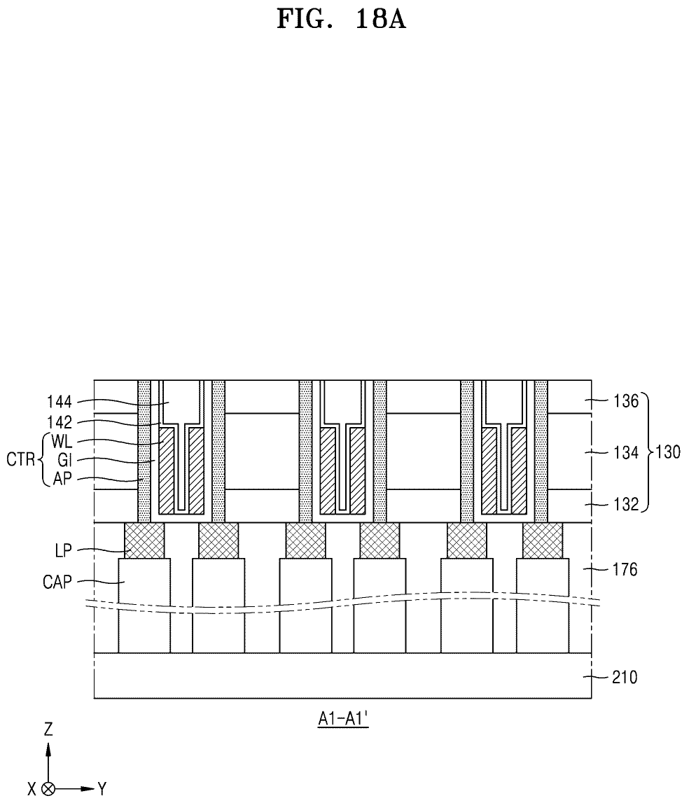

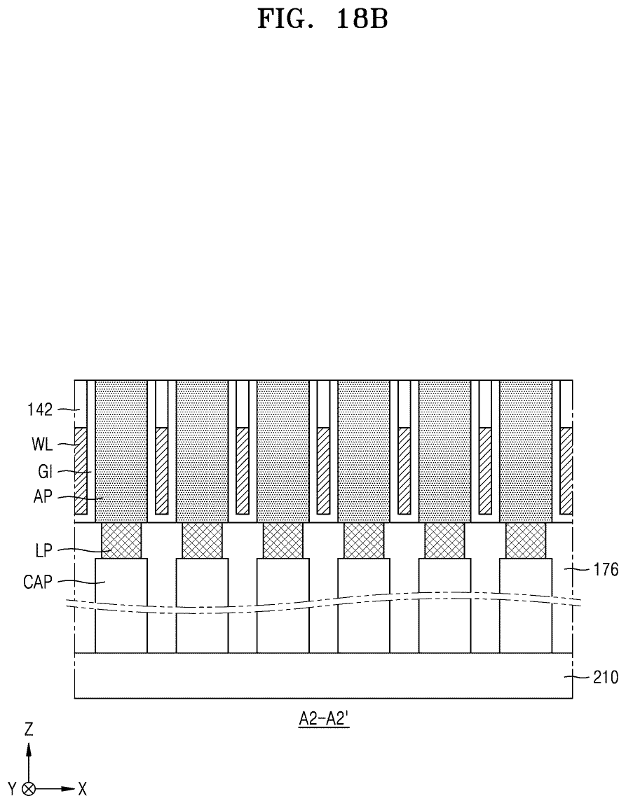

Referring to FIGS. 18A and 18B, a portion of the insulating liner 142 and a portion of the gate insulating layer GI, the portions being disposed on the upper surface of the mold structure 130, may be removed so that the upper surface of the mold structure 130 and the upper surface of the active semiconductor layer AP may be exposed again.

A process for removing the portion of the insulating liner 142 and the portion of the gate insulating layer GI may be a grinding or chemical mechanical polishing (CMP) process, and after the grinding or CMP process, an upper surface of the buried insulating layer 144, the upper surface of the active semiconductor layer AP, and the upper surface of the mold structure 130 may be disposed coplanar with each other.

Referring to FIGS. 19A and 19B, the intermediate line layer BULp may be formed on the upper surface of the buried insulating layer 144, the upper surface of the active semiconductor layer AP, and the mold structure 130.

In embodiments, the intermediate line layer BULp may include an oxide semiconductor, and may include, for example, the same material as the active semiconductor layer AP. In other embodiments, the intermediate line layer BULp may include an oxide semiconductor, and may include, for example, a material different from a material of the active semiconductor layer AP.

Thereafter, a bit line layer BLp may be formed on the intermediate line layer BULp. In embodiments, the bit line layer BLp may include Ti, TiN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof.

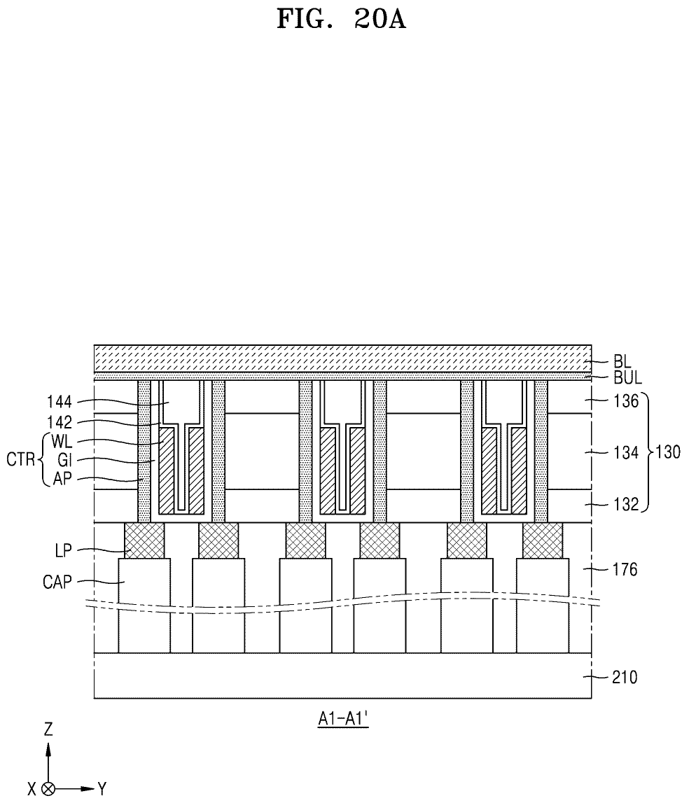

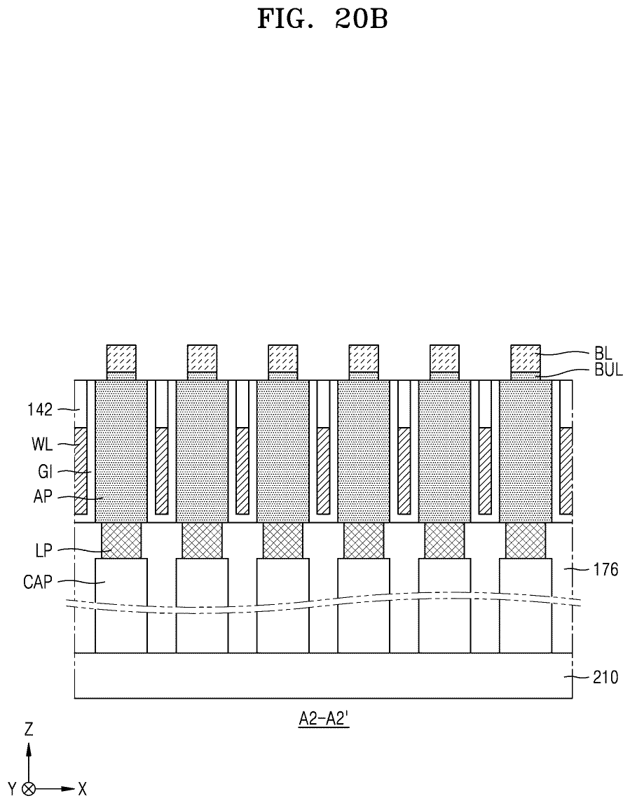

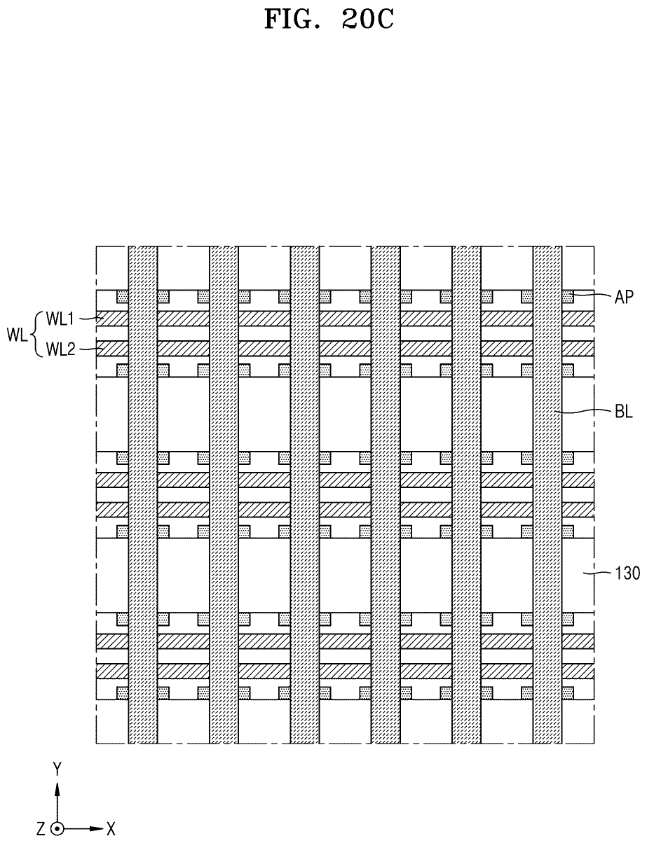

Referring to FIGS. 20A, 20B, and 20C, a mask pattern extending in the second horizontal direction Y may be formed on the bit line layer BLp (see FIG. 19A), and the bit line layer BLp and the intermediate line layer BULp may be patterned by using the mask pattern as an etching mask so that the bit line BL and the intermediate line BUL may be formed.

In embodiments, the bit line BL and the intermediate line BUL may be sequentially patterned in the same process, and accordingly, a sidewall of the bit line BL may be aligned with a sidewall of the intermediate line BUL.

As shown in FIG. 20A, the intermediate line BUL may have a line shape extending in the second horizontal direction Y, a portion of a bottom surface of the intermediate line BUL may be in contact with the upper surface of the active semiconductor layer AP, and the entire upper surface of the intermediate line BUL may be in contact with the entire bottom surface of the bit line BL.

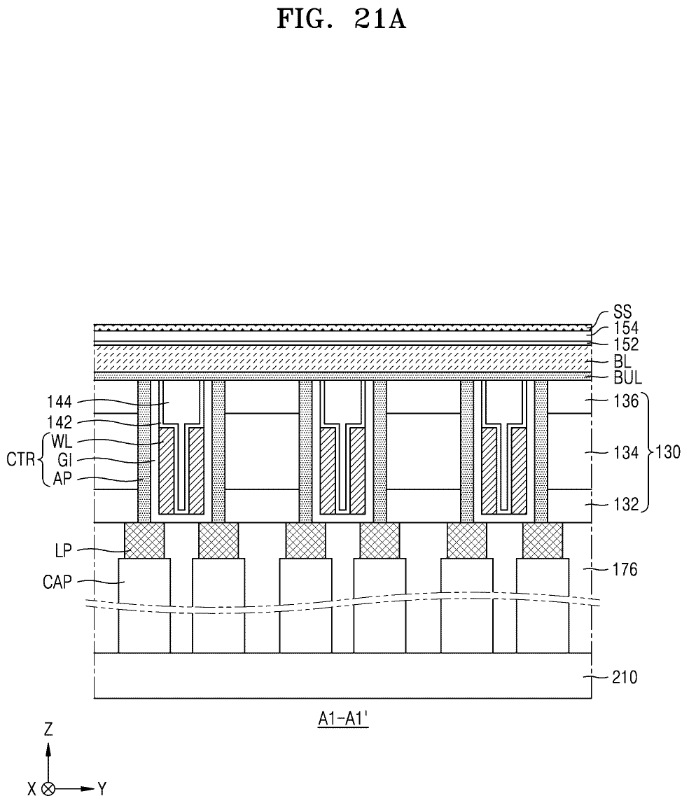

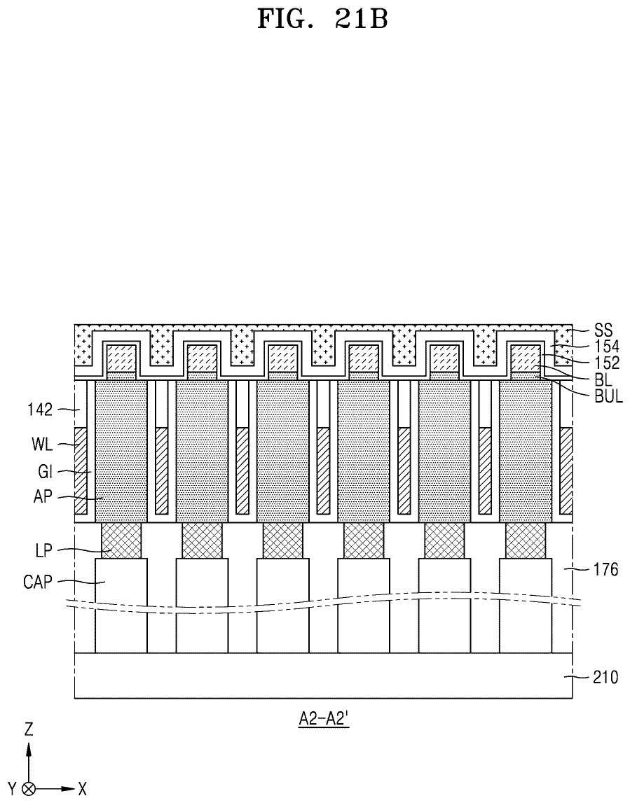

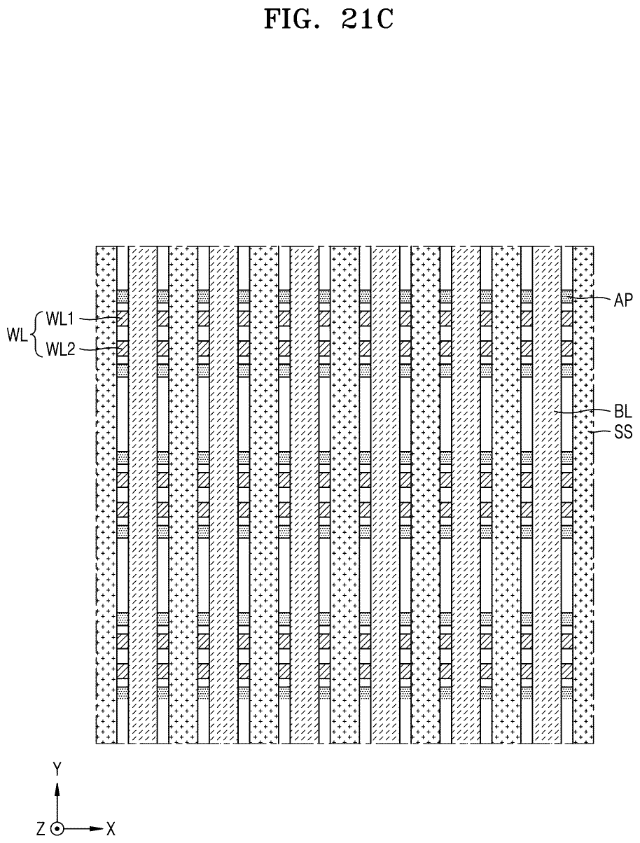

Referring to FIGS. 21A, 21B, and 21C, the first bit line insulating layer 152 and the second bit line insulating layer 154 may be sequentially formed on the intermediate line BUL and the bit line BL, and the shield metal layer SS may be formed on the second bit line insulating layer 154.

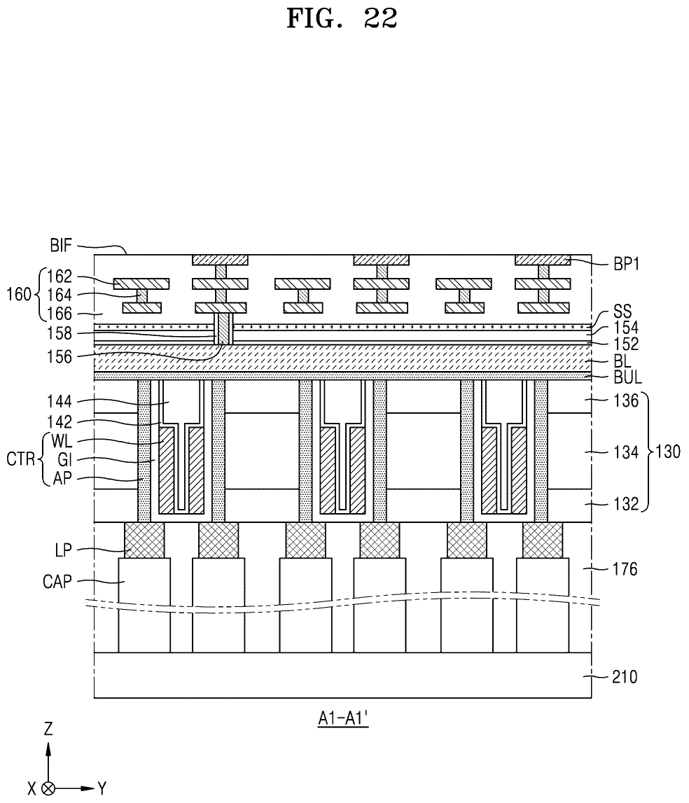

Referring to FIG. 22, the cell wiring structure 160 may be formed on the shield metal layer SS. The cell wiring structure 160 may include the cell wiring layer 162, the cell contact 164, and the cell insulating layer 166. In addition, the bit line contact 156 connecting the cell wiring layer 162 and the bit line BL to each other may be further formed. A sidewall of the bit line contact 156 may be surrounded by the bit line contact spacer 158 in plan view, and the bit line contact 156 may be electrically insulated from the shield metal layer SS by the bit line contact spacer 158.

The first bonding pad BP1 may be provided within the cell insulating layer 166 of the cell wiring structure 160. The first bonding pad BP1 may be electrically connected to the cell wiring layer 162. An upper surface of the cell insulating layer 166 may be disposed coplanar with the upper surface of the first bonding pad BP1, and the upper surface of the cell insulating layer 166 may be referred to as the bonding interface BIF.

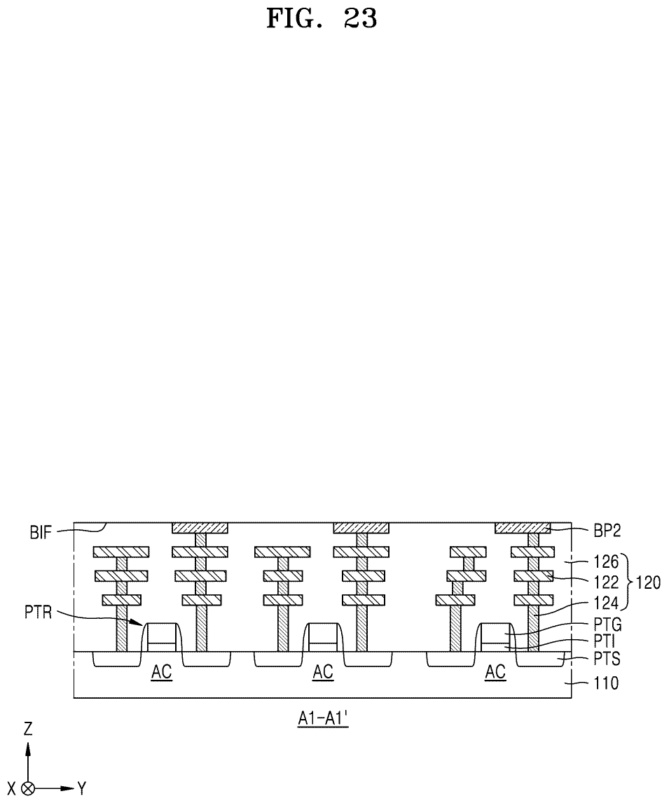

Referring to FIG. 23, the active area AC may be formed on the substrate 110, and the peripheral circuit transistor PTR may be formed on the active area AC. For example, the peripheral circuit transistor PTR may include the gate electrode PTG, the gate insulating layer PTI, and the source/drain area PTS.

Thereafter, the peripheral circuit line 122 and the peripheral circuit contact 124 electrically connected to the substrate 110 and the peripheral circuit transistor PTR may be formed, and the peripheral circuit insulating layer 126 covering or overlapping the peripheral circuit line 122 and the peripheral circuit contact 124 may be formed on the substrate 110. The peripheral circuit insulating layer 126 may be formed by using an oxide film, a nitride film, a low-k dielectric film, or a combination thereof.

The second bonding pad BP2 may be provided within the peripheral circuit insulating layer 126. The second bonding pad BP2 may be electrically connected to the peripheral circuit line 122. The upper surface of the peripheral circuit insulating layer 126 may be disposed coplanar with an upper surface of the second bonding pad BP2, and the upper surface of the peripheral circuit insulating layer 126 may be referred to as the bonding interface BIF.

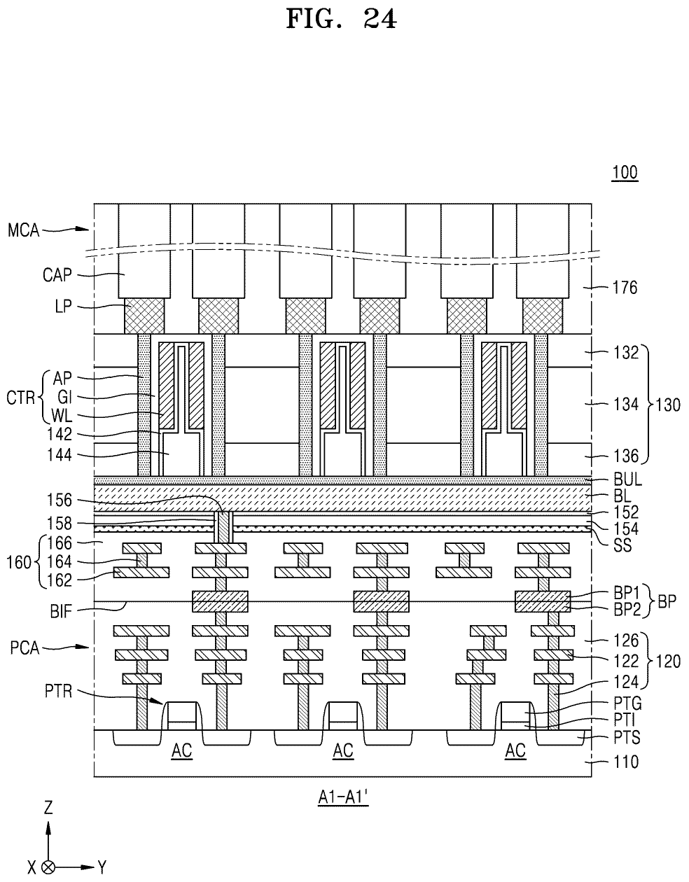

Referring to FIG. 24, the peripheral circuit area PCA and the cell array area MCA may be bonded to each other so that the cell wiring structure 160 and the peripheral circuit line structure 120 are in contact with each other. In embodiments, the first bonding pad BP1 and the second bonding pad BP2 may be in contact with each other at the bonding interface BIF, and the cell insulating layer 166 and the peripheral circuit insulating layer 126 may be in contact with each other at the bonding interface BIF.

Thereafter, the carrier substrate 210 may be removed.

By performing the process described above, the semiconductor device 100 may be completed.

According to embodiments, the peripheral circuit area PCA and the cell array area MCA may be manufactured by using separate wafers, respectively, and may be bonded to each other by using the bonding pad BP, and when the cell array area MCA is formed, the cell array area MCA may be first formed and then the cell transistor CAP may be formed. Accordingly, thermal damage to the cell transistor CTR may be prevented or minimized.

In a semiconductor device including an oxide semiconductor channel, according to the comparative example, after an active semiconductor layer is formed on a sidewall of a mold structure, a recess is formed by removing a portion of the active semiconductor, and a bit line is formed by burying a portion of a bit line within the recess (i.e., at a position from which the portion of the active semiconductor layer is removed). In this case, coupling capacitance due to the portion of the bit line arranged within the recess may be relatively high.

According to embodiments, the process of forming a recess by removing a portion of the active semiconductor layer AP may not be performed, and accordingly, because the entire area of the bit line BL may be shielded by the shield metal layer SS, significantly low coupling capacitance may be shown compared to the comparative example.

Moreover, when the intermediate line BUL is disposed between the bit line BL and the active semiconductor layer AP, electrical resistance between the bit line BL and the active semiconductor layer AP may be significantly reduced, and the semiconductor device 100 may have excellent electrical performance.

In the embodiments described above, it is described with reference to FIGS. 18A, 18B, 19A, and 19B that the bit line BL and the intermediate line BUL are patterned in the same process. However, in other embodiments, the intermediate line layer BULp is first formed, a mask pattern is formed on the intermediate line layer BULp, and the intermediate line layer BULp is patterned, so that the intermediate line BUL may be formed. Thereafter, the bit line layer BLp is formed to cover or overlap the intermediate line BUL, a mask pattern is formed on the bit line layer BLp, and the bit line layer BLp is patterned, so that the bit line layer BLp may be formed. In this embodiment, the second width w2 of the bit line BL may be different from the first width w1 of the intermediate line BUL. For example, the second width w2 of the bit line may be greater than the first width w1 of the intermediate line BUL, and accordingly, a contact area between the bit line BL and the intermediate line BUL may be further increased. In this case, the semiconductor device 100A described with reference to FIGS. 7 to 9 may be manufactured.

According to the inventive concept, coupling between bit lines may be reduced, and contact resistance may be reduced by an increased contact area between a bit line and a channel layer. Therefore, the semiconductor device may have excellent electrical performance.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate;
a peripheral circuit area on the substrate; and
a cell array area at a distance from the substrate that is different from a distance of the peripheral circuit area from the substrate, wherein the cell array area is electrically connected to the peripheral circuit area by a bonding pad,
wherein the cell array area comprises:
a mold structure extending in a first horizontal direction;
an active semiconductor layer on a sidewall of the mold structure and comprising a first oxide semiconductor;
a word line on a sidewall of the active semiconductor layer;
a cell capacitor on an upper surface of the active semiconductor layer;
a bit line on a bottom surface of the active semiconductor layer and extending in a second horizontal direction that intersects the first horizontal direction; and
an intermediate line between the bottom surface of the active semiconductor layer and the bit line, the intermediate line extending in the second horizontal direction and comprising a second oxide semiconductor.

2. The semiconductor device of claim 1, wherein the upper surface of the active semiconductor layer is coplanar with an upper surface of the mold structure, and
wherein the bottom surface of the active semiconductor layer is coplanar with a bottom surface of the mold structure.

3. The semiconductor device of claim 2, wherein the intermediate line is between the bottom surface of the mold structure and the bit line.

4. The semiconductor device of claim 1, wherein the bit line has a planar top surface and a planar bottom surface, and
wherein the bit line has a uniform thickness along a length of the bit line.

5. The semiconductor device of claim 1, wherein the first oxide semiconductor comprises at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), or zirconium zinc tin oxide (ZrₓZn_{y}Sn_{z}O).

6. The semiconductor device of claim 1, wherein the second oxide semiconductor comprises at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), or zirconium zinc tin oxide (ZrₓZn_{y}Sn_{z}O).

7. The semiconductor device of claim 1, further comprising:
a shield metal layer on the bit line; and
a bit line insulating layer on a sidewall of the bit line and on a sidewall of the intermediate line, between the shield metal layer and the bit line, and between the shield metal layer and the intermediate line.

8. The semiconductor device of claim 7, wherein the sidewall of the intermediate line is aligned with the sidewall of the bit line.

9. The semiconductor device of claim 8, wherein the intermediate line has a first width in the first horizontal direction,
wherein the bit line has a second width in the first horizontal direction, and
wherein the second width is equal to the first width.

10. The semiconductor device of claim 1, wherein the bit line is on a sidewall of the intermediate line.

11. The semiconductor device of claim 10, wherein the intermediate line has a first width in the first horizontal direction,
wherein the bit line has a second width in the first horizontal direction, and
wherein the second width is greater than the first width.

12. A semiconductor device comprising:
a substrate;
a peripheral circuit area on the substrate; and
a cell array area on the peripheral circuit area,
wherein the cell array area comprises:
a plurality of mold structures extending in a first horizontal direction;
a plurality of active semiconductor layers spaced apart from each other in the first horizontal direction, wherein ones of the plurality of active semiconductor layers are between adjacent mold structures from among the plurality of mold structures and extend in a vertical direction that intersects the first horizontal direction;
a first word line and a second word line spaced apart from each other between adjacent mold structures from among the plurality of mold structures, wherein the first word line and the second word line extend in the first horizontal direction;
a plurality of bit lines that are at a first distance from the substrate that is less than a second distance of the plurality of active semiconductor layers from the substrate and less than a third distance of the plurality of mold structures from the substrate, wherein the plurality of bit lines extend in a second horizontal direction that intersects the first horizontal direction and the vertical direction; and
a plurality of intermediate lines between respective ones of the plurality of active semiconductor layers and respective ones of the plurality of bit lines and between the plurality of mold structures and the plurality of bit lines, and extending in the second horizontal direction.

13. The semiconductor device of claim 12, wherein the plurality of intermediate lines are on upper surfaces of the plurality of bit lines, respectively, and
wherein upper surfaces of the plurality of intermediate lines are in contact with bottom surfaces of the plurality of active semiconductor layers, respectively.

14. The semiconductor device of claim 12, wherein respective upper surfaces of the plurality of active semiconductor layers are coplanar with respective upper surfaces of the plurality of mold structures, and
wherein respective bottom surfaces of the plurality of active semiconductor layers are coplanar with respective bottom surfaces of the plurality of mold structures.

15. The semiconductor device of claim 12, further comprising:
a shield metal layer in a space between adjacent bit lines from among the plurality of bit lines and extending in the second horizontal direction.

16. The semiconductor device of claim 12, wherein sidewalls of the plurality of intermediate lines are aligned with sidewalls of the plurality of bit lines, respectively,
wherein each of the plurality of intermediate lines has a first width in the first horizontal direction,
wherein each of the plurality of bit lines has a second width in the first horizontal direction, and
wherein the second width is equal to the first width.

17. The semiconductor device of claim 12, wherein the plurality of bit lines are on respective sidewalls of the plurality of intermediate lines,
wherein each of the plurality of intermediate lines has a first width in the first horizontal direction,
wherein each of the plurality of bit lines has a second width in the first horizontal direction, and
wherein the second width is greater than the first width.

18. A semiconductor device comprising:
a peripheral circuit area comprising a substrate and a peripheral circuit transistor; and
a cell array area on the peripheral circuit area, wherein the cell array area comprises:
a mold structure extending in a first horizontal direction;
an active semiconductor layer on a sidewall of the mold structure and comprising a first oxide semiconductor;
a word line on a sidewall of the active semiconductor layer;
a gate insulating layer between the sidewall of the active semiconductor layer and the word line;
a landing pad on an upper surface of the active semiconductor layer;
a cell capacitor on the landing pad;
an intermediate line on a bottom surface of the active semiconductor layer and on a bottom surface of the mold structure, the intermediate line extending in a second horizontal direction and comprising a second oxide semiconductor;
a bit line on a bottom surface of the intermediate line and extending in the second horizontal direction;
a bit line insulating layer on the bit line and on a sidewall of the intermediate line; and
a shield metal layer at a side of the bit line with the bit line insulating layer therebetween.

19. The semiconductor device of claim 18, wherein the first oxide semiconductor and the second oxide semiconductor each comprise at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), or zirconium zinc tin oxide (ZrₓZn_{y}Sn_{z}O).

20. The semiconductor device of claim 18, wherein the upper surface of the active semiconductor layer is coplanar with an upper surface of the mold structure,
wherein the bottom surface of the active semiconductor layer is coplanar with the bottom surface of the mold structure, and
wherein the bit line has a planar top surface and a planar bottom surface.
